(19) United States
(12) Patent Application Publication
(10) Pub. No.: US 2010/0126554 A1
(43) Pub. Date: May 27, 2010

(54) STAGGERED LIGHT COLLECTORS FOR CONCENTRATOR SOLAR PANELS

(75) Inventors: John Paul MORGAN, Toronto (CA); Eric Andres MORGAN, Toronto (CA)

Correspondence Address: BORDEN LADNER GERVAIS LLP;Anne Kinsman, WORLD EXCHANGE PLAZA, 100 QUEEN STREET SUITE 1100, OTTAWA, ON, K1P 1J9, CA

(73) Assignee: MORGAN SOLAR INC., Toronto (CA)

(21) Appl. No.: 12/554,481

(22) Filed: Sep. 4, 2009

Related U.S. Application Data
(60) Provisional application No. 61/094,168, filed on Sep. 4, 2008.

(51) Int. Cl. H01L 31/052

(52) U.S. Cl. 136/246

(57) ABSTRACT

A solar panel assembly with a first group of spaced-apart solar energy collector modules and a second group of spaced-apart solar energy collector modules. The first and second groups lie in respective parallel planes, which define an air gap therebetween, and are staggered with respect to each other. The staggering of the groups allows for light not harvested by the first row to be harvested by the second row and provides a low dead-space characteristic for the solar panel assembly. The gap between the planes and the space between individual solar energy collector modules of a same group allow for improved heat dissipation in the modules and for the solar panel assembly to offer low resistance to wind.

### CROSS REFERENCE TO RELATED APPLICATIONS

This application claims the benefit of priority of U.S. Provisional Patent Application No. 61/094,168 filed Sep. 4, 2009, which is incorporated herein by reference in its entirety.

### FIELD OF THE INVENTION

The present invention relates generally to solar power. More particularly, the present invention relates to reducing wind loading and improving heat dissipation for tracker mounted solar power systems, especially for concentrated photovoltaic systems.

### BACKGROUND OF THE INVENTION

Concentrated photovoltaic (CPV) systems are known and currently produced by a number of companies around the world including Amonix, Concentrix, and Sol3g. The systems are based on the idea of making a solar module using an optic, such as a lens or mirror, to collect light over a large area and concentrate it onto small photovoltaic (PV) cells which then convert that light to electricity.

The optics can be a Fresnel lens, a Cassegrain optic, a parabolic mirror, a light-guide solar optic, or any other focusing optic, operating either with or without secondary optics. In order to function, all of these optical systems require that light be incident from a certain specified direction; typically the angle of incidence is perpendicular to the top surface of the module, which is called normal incidence. In order to maintain normal incidence of the light from the sun, the CPV module is tilted and oriented by a tracking mechanism of some description so that it faces the sun. The tracking mechanism must continuously adjust the position of the CPV module so that the module follows the sun as it moves across the sky. It is also possible to change the angle of incidence of the light on the CPV module using active electro-optic layers, which are electronically controlled and change the incidence angle of the light to allow for the optics to function.

In conventional CPV systems using trackers, the modules are arranged in a grid to cover a large area. Trackers can accommodate very large areas of modules on the order of 200 square meters. In order to maximize the energy produced, the modules are packed close together with small gaps between them; this maximizes light gathered for a given tracker. It does however present a large, flat wall to oncoming wind, which can put considerable force onto the tracker. Force due to the wind, or wind loading, is a primary design consideration for any solar tracker system. For example, conventional panels on a 10 meter by 10 meter tracker with wind incident head-on at 20 meters per second will experience a force of 42 kilo-Newtons due to the wind. Because the tracker needs to accurately orient the panels towards the sun, in most cases keeping the incident sunlight normal to the panel to within less than 0.1 degrees, the tracker cannot bend or deform to a great degree and as such must be made of enough steel so as to be stiff enough to resist the wind.

In any CPV system, a great deal of light energy is concentrated at the PV cells. High efficiency cells which are available on the market have conversion efficiencies of around 37%, this implies that 37% of the light incident on the cell is converted into electrical energy. The majority of the remainder of the light is converted into heat. So for every watt of usable electrical energy created, almost 1.7 watts of heat is created. This heat must be dissipated. PV cell performance decreases as temperature increases, and excessive overheating can result in permanent damage to the modules, so effective heat shedding is required to make CPV work.

Some systems employ active cooling, which involves water or another heat exchange fluid being pumped through a heat exchanger to remove heat from the PV cells. However, most systems employ passive cooling, wherein heat only leaves the system through irradiative and convective mechanisms into the surrounding air. The primary mode of heat dissipation is convection; the irradiative component of shed heat is negligible by comparison. Convection occurs when air molecules come into contact with the module, become hot, and then diffuse away from the module.

In Fresnel lens-based and Cassegrain optic-based systems, the optic is positioned above the PV cells and the PV cells are at the bottom of the module. The PV cells are generally mounted on some sort of dielectric substrate, such as alumina, which is in turn attached to a heat sink. Often, the enclosure of the module is employed as the heat sink. When the module is facing straight up and the PV cells are at the bottom of the enclosure, the heated air rises and becomes partially trapped against the enclosure. This results in a low degree of air circulation and can result in excessive heating of the system.

Spacing the modules and leaving gaps between them can address both the issue of high wind loading and poor heat dissipation. This has the detrimental consequence of reducing the area over which light can be gathered by the modules, diminishing overall efficiency.

Improvements in wind-loading and heat dissipation aspects of solar modules are therefore desirable.

### SUMMARY OF THE INVENTION

In a first aspect, there is provided a photovoltaic tracking solar energy capturing and conversion system. The system comprises a first group of spaced-apart solar energy collectors modules secured to a support. The system also comprises a second group of spaced-apart solar energy collectors modules secured to said support, each solar energy collector module of said first and second groups of solar energy collector modules including an array of photovoltaic cells associated with a respective optical light collector element, the first and second groups of solar energy collectors modules defining two substantially parallel planes separated by an air gap, said air gap dimensioned to ensure heat dissipation to prevent overheating of the photovoltaic cells, the first and second groups of solar energy collectors modules being staggered with respect to each other by an amount that allows the optical light collector elements of each solar energy collector module to be exposed to substantially equal levels of solar energy for capture by said optical light collector elements and associated photovoltaic cells, wherein the two parallel planes and the staggered positioning of the first and second groups of solar energy collector modules reduce wind load upon the solar energy collector modules. The system further comprises a tracking system that orients said support to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

In a second aspect, there is provided a compact photovoltaic tracking solar energy capturing and conversion system. The system comprises a first group of solar energy collectors modules secured to a support and a second group of solar energy collectors modules secured to a support. Each solar energy collector module of said first and second groups of solar energy collector modules including an array of photovoltaic cells each associated with a respective light guide optical concentrator, each solar energy collector module of the first and second groups being spaced apart from an adjacent solar energy collector module of its respective group by a distance substantially equal to a width of an active area of the photovoltaic cell, plus the width of a mounting section, the first and second groups of solar energy collector modules defining two substantially parallel planes, the substantially parallel planes being separated by an air gap, wherein the solar energy collector modules of the first and second groups are staggered with respect to each other by an amount that provides substantial equal exposure to solar energy minus a shadowing area created by a lateral mounting portion of the photovoltaic cell to said support. The system further comprises a tracking system that orients said support to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

In a third aspect, there is provided a method of dissipating heat accumulation in concentrated photovoltaic solar panels caused by an optic concentrator. The method comprises steps of providing a first group of solar energy collectors modules secured to a support and providing a second group of solar energy collectors modules secured to the support. Each collector module of said first and second groups of solar energy collector modules including an array of photovoltaic cells each associated with a respective optic concentrator, each solar energy collector module of the first and second groups of solar energy collector modules being spaced apart from another solar energy collector module of its respective group by a distance substantially equal to a width of an active area of a light capture area of a solar energy collector module, to create a heat dissipation pathway, said the first and second groups of solar energy collector modules defining substantially parallel planes separated by an air gap to create an additional heat dissipation pathway, wherein the solar energy collector modules from the first and second groups are staggered with respect to each other by an amount that provides substantially equal exposure to the solar energy minus a shadowing area created by a lateral mounting portion of the photovoltaic cell to said support. The method further comprises a step of providing a tracking system that orients said support to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

### BRIEF DESCRIPTION OF THE DRAWINGS

Embodiments of the present invention will now be described, by way of example only, with reference to the attached Figures, wherein:

FIG. 1 shows a typical flat plate solar panel;

FIG. 2 shows an isometric view of a Fresnel lens concentrator system;

FIG. 3 shows an isometric view of solar power module made using an array of Fresnel lenses;

FIG. 4 shows examples of different optical systems that can be used for concentration;

FIG. 5 shows a light-guide solar module made using an array of Cassegrain optics;

FIGS. 6a and 6b show a two axis tracker system for concentrated photovoltaic modules;

FIGS. 7a, 7b, 7c and 7d show a single axis tracker system for solar panels and concentrated photovoltaic modules;

FIGS. 8a and 8b show a solar module made by separating the light collectors into rows and spacing those rows;

FIGS. 9a, 9b and 9c show a solar module made by separating the light collectors into rows and staggering those rows;

FIGS. 10a and 10b show a receiver assembly involving a printed circuit board and a photovoltaic cell;

FIGS. 11a and 11b show a Fresnel lens concentrator system employing a secondary optic coupled directly to a photovoltaic cell;

FIGS. 12a and 12b show a solar power module made using an array of Fresnel lenses that has fins on its bottom for heat dissipation with indications of the movement of hot air about the module;

FIGS. 13a and 13b show a Fresnel lens based concentrated photovoltaic system made by separating the light collectors into rows and spacing those rows to allow hot air to rise between them;

FIGS. 14a, 14b and 14c show the action of a light-guide solar optic on incident normal light;

FIGS. 15a and 15b show a light-guide solar optic based concentrated photovoltaic system made by separating the light collectors into rows and spacing those rows;

FIG. 16 shows a light-guide solar optic based concentrated photovoltaic module made from the system in the previous figure;

FIGS. 17a and 17b show a comparison between dead-space and active collector area on the module from the previous figure;

FIGS. 18a and 18b show a light-guide solar optic based concentrated photovoltaic system made by separating the light collectors into rows and staggering those rows;

FIG. 19 shows a light-guide solar optic based concentrated photovoltaic module made from the system in the previous figure;

FIG. 20 shows a comparison between dead-space and active collector area on the module from the previous figure;

FIGS. 21a and 21b show a direct comparison between the dead-space and active collector area for the modules in FIGS. 16 and 19;

FIGS. 22a and 22b show a Fresnel lens based concentrated photovoltaic system made by separating the light collectors into rows and staggering those rows;

FIG. 23 shows a Fresnel lens based module made from the system in the previous figure;

FIG. 24a shows a light-guide solar optic based module where light collector rows are separated by small gaps;

FIG. 24b shows a computational fluid dynamics thermal model of the light-guide solar optic based module of FIG. 24a;

FIG. 25a shows a light-guide solar optic based module where light collector rows are vertically staggered;

FIG. 25b shows a computational fluid dynamics thermal model of the light-guide solar optic based module of FIG. 25a;

FIG. 26 shows a dual axis tracker;

FIGS. 27a, 27b and 27c show light-guide solar optic based modules with vertically staggered light collector rows mounted on a dual axis tracker;

FIGS. 28a and 28b show solid flat solar panels mounted on a dual axis tracker;

FIG. 29 shows streamlines, indicating airflow around a solid flat solar panel, made using computational fluid dynamic modeling;

FIG. 30 shows streamlines, indicating airflow around a light-guide solar optic based module where the light collector rows are separated by small gaps, made using computational fluid dynamic modeling;

FIG. 31 shows streamlines, indicating airflow around a light-guide solar optic based module where the light collector rows are vertically staggered, made using computational fluid dynamic modeling;

FIGS. 32a and 32b show streamlines indicating airflow around a large array of solid flat solar panels;

FIGS. 33a and 33b show streamlines indicating airflow around a large array of light-guide solar optic based modules where the light collector rows are vertically staggered;

FIGS. 34a and 34b show an embodiment of the light-guide solar module with staggered light collector rows;

FIG. 35 shows the results of a modeling analysis to find the optimal light collector row spacing for thermal dissipation; and

FIGS. 36a and 36b show the results of computational fluid dynamic thermal models of two different light-guide solar optic based modules where the light collector rows are separated by small horizontal gaps in one module and by vertical staggering in the other module.

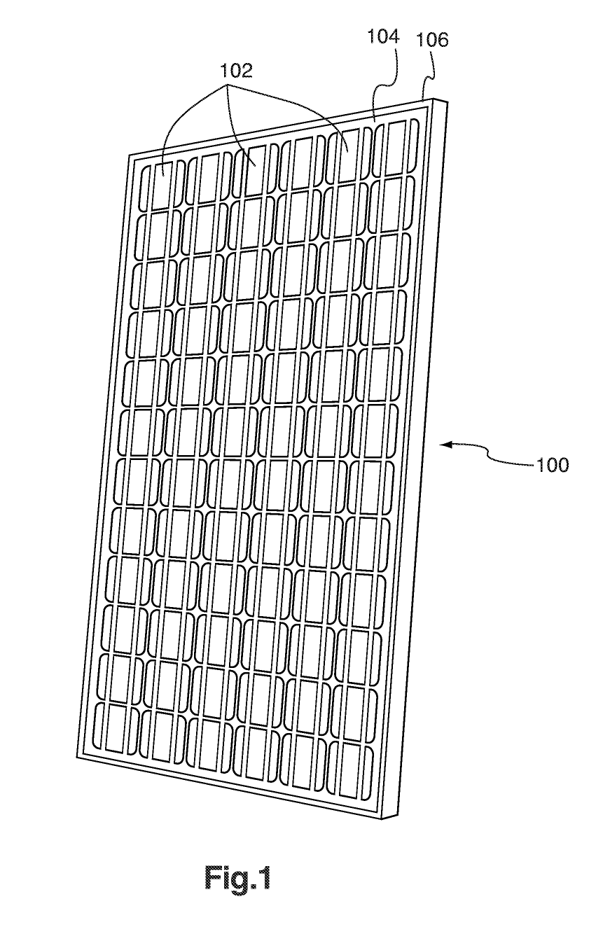

### DETAILED DESCRIPTION OF THE INVENTION

The present invention is related to an arrangement of solar energy collector modules (SECMs). A first group of spaced-apart SECMs defines a first plane which is substantially parallel to a second plane defined by a second group of spaced-apart SECMs The first and second planes are separated by an air gap, and the first and second groups of SECMs are staggered with respect to each other. The staggering of the first and second groups of SECMs allows for light not harvested by the first group to be harvested by the second row and provides a low dead-space characteristic for the arrangement of solar energy collector modules. The air gap between the first and second planes allows for improved heat dissipation in the modules and prevents overheating of photovoltaic elements comprised in the SECMs. Further, the air gap and the spacing between SECMs of a same group allows for low resistance to wind. The arrangement of SECMs can be secured to a tracking system to allow optimum solar energy harvesting throughout the day.

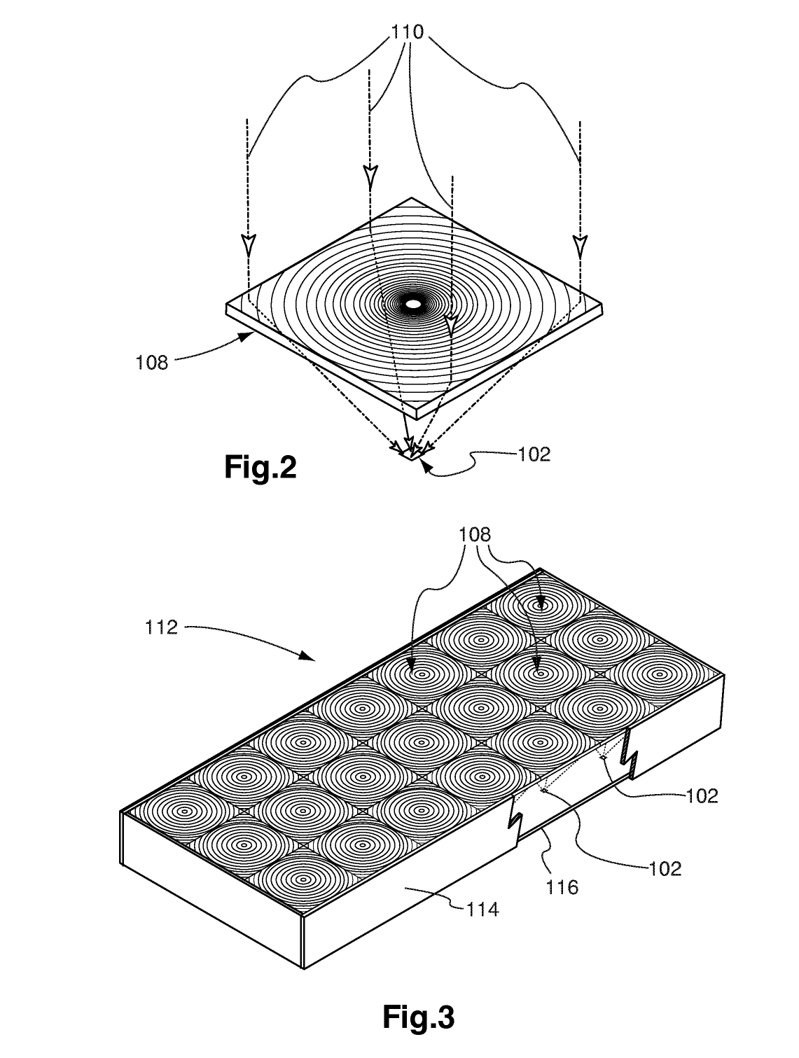

Concentrated Photovoltaics (CPV) modules employ optics as light collectors, which can also referred to as optical light collector elements, to capture and concentrate light onto PV cells. FIG. 2 shows a single CPV unit having a Fresnel lens 108, concentrating incident normal light 110 onto a high efficiency PV cell 102. The Fresnel lens is an exemplary optical light collector element. FIG. 3 shows an isometric view of a Fresnel lens-based CPV module 112, comprised of an array of Fresnel lenses 108. The enclosure 114 of the CPV module is made of a stiff material like aluminum. A cutaway section 116 shows PV cells 102 underneath the lenses attached to the enclosure 114. The PV cells 102 would not in practice be naked, but would be encapsulated in a receiver assembly of some sort. Receivers will be described later, but in this document the terms receiver and PV cell will be used interchangeably. The top surfaces of all the Fresnel lenses 108 are the light collectors of this module. The frame around the module is dead-space.

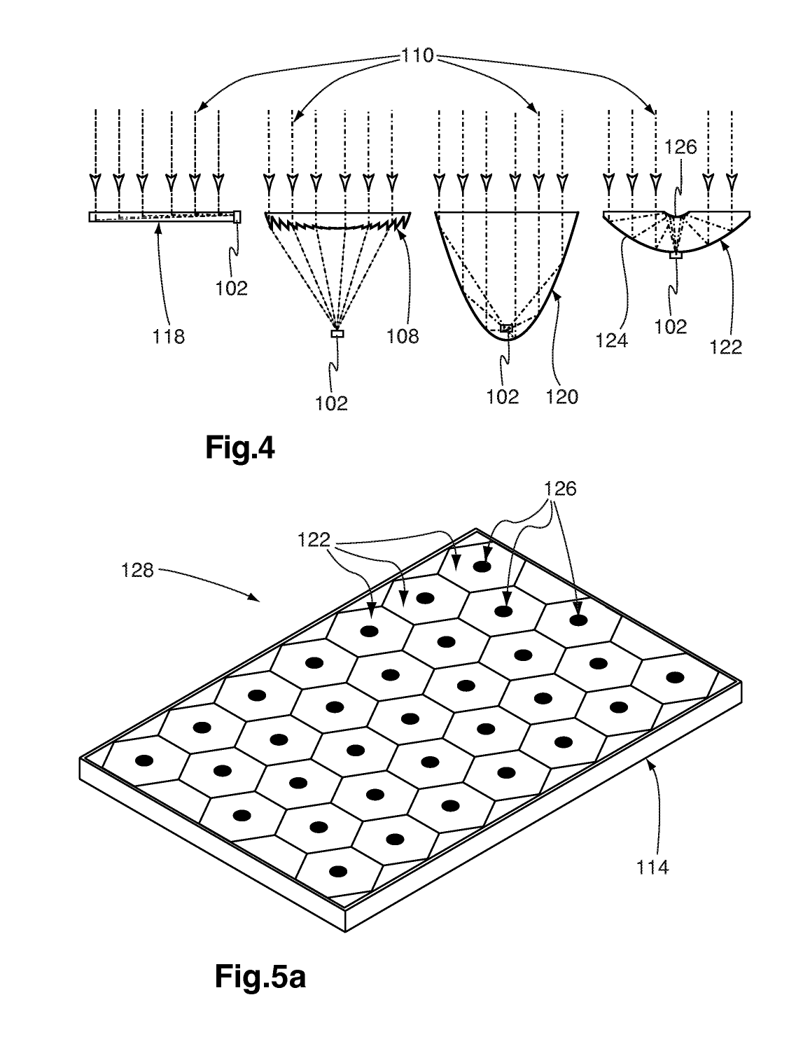

Non-Fresnel optics can also be used as optical light collector elements to make CPV systems. Examples of various optical light collector elements are shown at FIG. 4. FIG. 4 shows cross sections of a variety of optical systems which can concentrate normal incident light 110 onto PV cells 102. A light-guide solar optic 118, such as the system described in U.S. patent application Ser. No. 12/113,705 titled “Light-guide Solar Panel and Method of Fabrication Thereof” is one example of such an optic. A Fresnel lens 108 is another system. Parabolic reflectors 120 concentrate light to a focal point where a PV cell can be positioned, and Cassegrain optics 122 use a parabolic primary mirror 124 and a hyperbolic secondary mirror 126 to concentrate incident normal incident light 110 onto a PV cell 102.

The current state of the art means of fabricating modules from any of the optical systems from FIG. 4 is to arrange the light collectors in a tightly packed array. Spaces between the light collectors are minimized in order to minimize dead-space in the module.

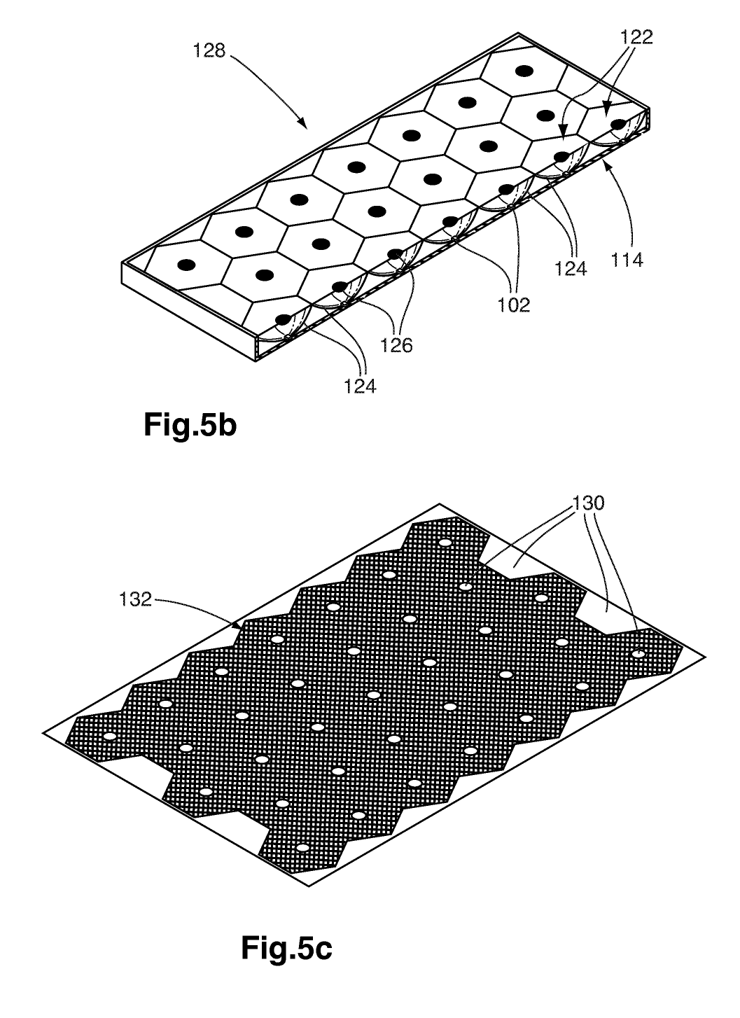

FIG. 5a shows another example module 128 where Cassegrain optics 122 are arranged in an array, with an aluminum enclosure 114 at the bottom which serves as a heat-sink for the PV cells 102. FIG. 5b shows a cut away view of the same module, with the primary parabolic mirror 124 and the secondary hyperbolic mirror 126 and the PV cells 102 shown. FIG. 5c shows the dead-space 130, including the dead-space occupied by the secondary mirror, in white and the light collector area 132 hashed out. Arranging the Cassegrain optics in a honeycomb pattern as shown is not the only way of arranging Cassegrain optics to make a module, but it is the way employed by SolFocus of California, USA.

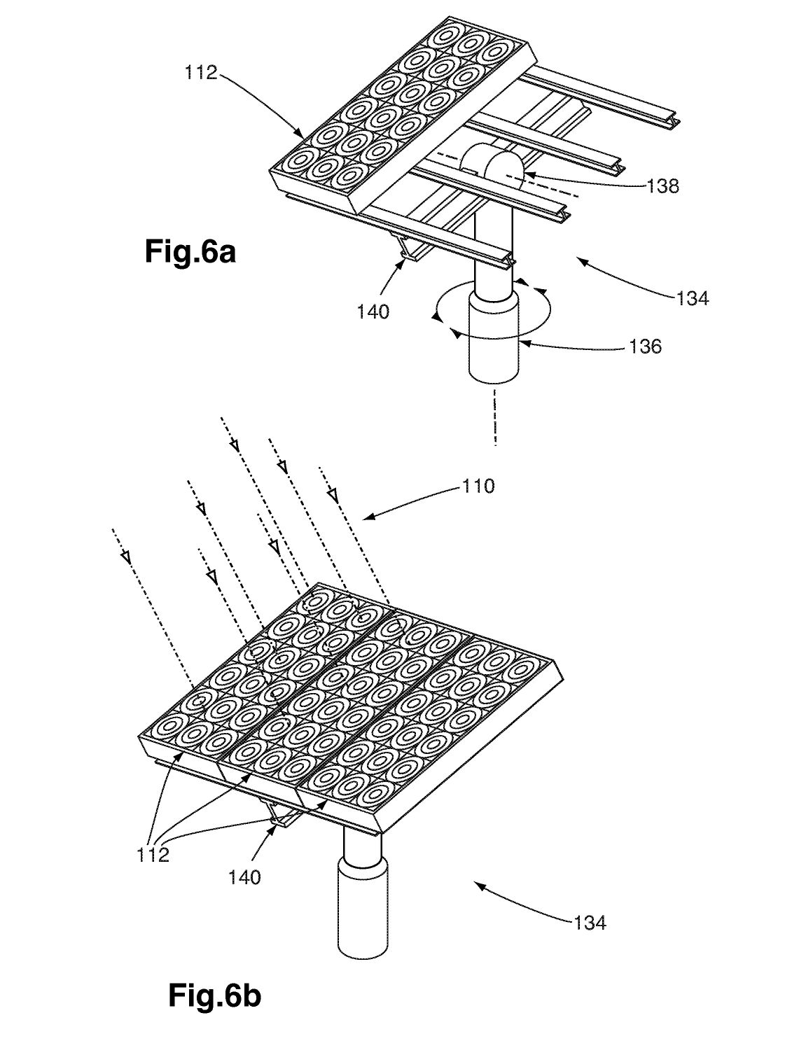

Most CPV systems employ dual axis trackers to follow the sun, shown in FIGS. 6a and 6b. FIG. 6a shows the tracker 134 with one Fresnel lens based modules 112. The tracker employs some sort of mechanism to rotate 136 and tilt 138 the modules in order to orient the modules throughout the day so that they face the sun. The tracker supports the modules using a support structure 140. FIG. 6b shows the tracker 134 with several modules 112 mounted. When the modules are facing the sun, direct normal irradiance 110 from the sun falls on the light collectors with an angle of incidence of zero degrees measured from the normal of the module. The incident sunlight 110 is perpendicular to the modules 112 top surface.

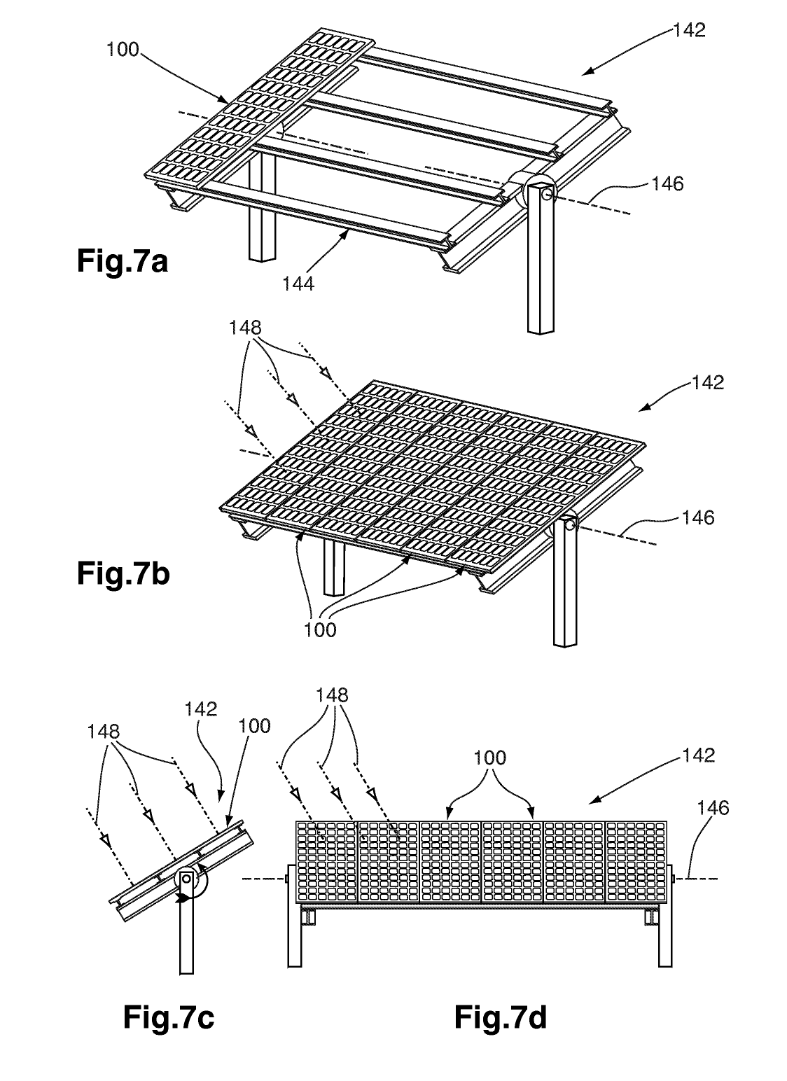

Some CPV systems, as well as some conventional photovoltaic systems, also use single axis trackers to follow the sun as shown in FIGS. 7a-7d. FIG. 7a shows a single axis tracker 142 with a single solar panel 100, and FIG. 7b shows a tracker 142 with many solar panels 100. As the name suggests, a single axis tracker 142 rotates a supporting frame 144 about a single axis of rotation 146. Single axis trackers 142 follow the daily east west motion of the sun through the sky but do not adjust for seasonal variation in the altitude of the sun. The incident light 148 is not normal to the top surface of the module; the incident light 148 is normal only in the plane shown in FIG. 7c, being the plane in which the tracker 142 rotates. In any other plane, as shown in FIG. 7d, the incident light 148 is not normal to the panels.

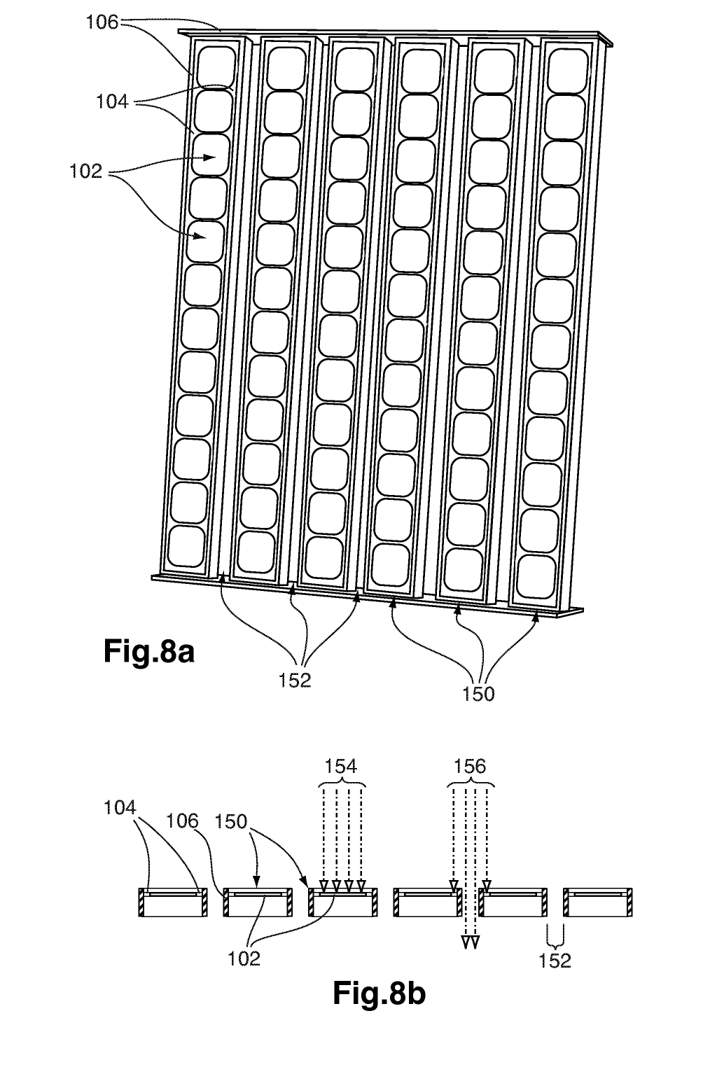

Both single axis and dual axis trackers shown in FIGS. 6 and 7 are small, holding only 3 and 6 modules, respectively, that are 1.5 meters by 0.8 meters. In practice, trackers used in solar farms are generally much larger, being able to support dozens of modules, with total collector areas between 50 square meters and 200 square meters. Modules are mounted on such trackers in an array generally as tight as possible in order to minimize dead-space. Dead-space is defined as area occupied by the modules that is not directly contributing to energy production by the modules. In other words, dead-space reduces total efficiency of the system by allowing light that falls on the system to be wasted. Tightly packing the modules creates design issues both from the perspective of shedding heat from the modules and in terms of wind loading. Leaving spaces between the modules however, or leaving spaces between the light collectors in the individual modules themselves, alleviates the wind loading and thermal issues to some extent but does so at the expense of light collection area by increasing dead-space. FIG. 8a shows the dead-space created by breaking up the module 100 into light collector rows 150 an adding lateral gaps 152 between them. When viewed from the edge, as in FIG. 8b, normal incident light 156 will pass through the gaps that are created and be wasted. Only the light 154 that directly strikes the PV cells 102 is harvested. The light 156 that hits the aluminum frame 106, the laminate 104, or the gaps 152 is lost.

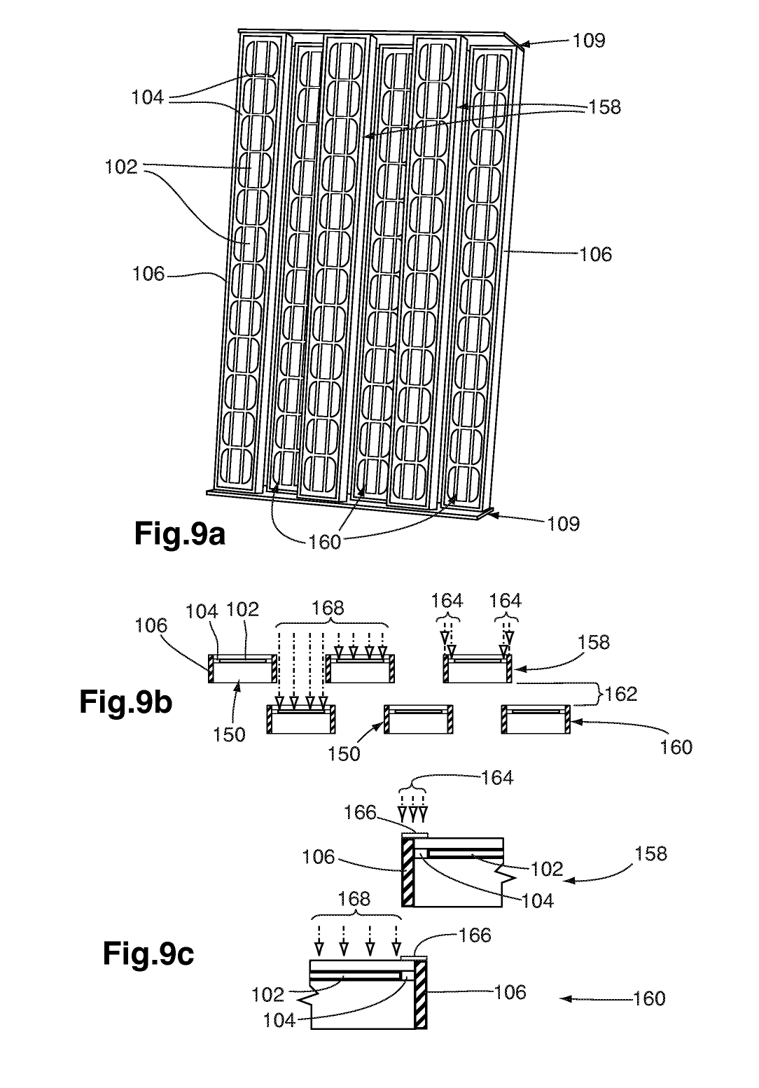

The present invention is to separate the light collectors of a module into a series of slat-like light collector rows that are staggered with respect to each other. This creates spaces between the light collectors for the purpose of reducing wind loading and improving heat dissipation without increasing the dead-space of the module. FIG. 9 shows a module broken up into light collector rows 158 and 160 that are staggered with no increase to dead-space. Each light collector row can be referred to as solar energy collector module. The upper rows 158, which forms a first group of solar energy collector modules, and the lower rows 160, which forms a second group of solar energy collector modules, are separated by a vertical gap 162. As shown in the exemplary embodiment of FIG. 9a, each solar energy collector module is secured to supports 109. The first group of solar energy collector modules is staggered with respect to the second group of solar energy modules in the sense that the upper and lower light collector rows do not overly directly above one another other. For greater certainty, the purpose of the present description, the word “staggered” is meant to include: arranged so that objects (e.g. groups of solar energy collector modules) are offset from each other. When viewed from the side, as in FIG. 9b, it can be seen that only light 164 that strikes the laminate 104 or frame 106 around the PV cells is lost. No light is lost through the gaps 162 between the top light collector rows 158 and the bottom light collector rows 160.

If the light collector rows 150 have any sort of frame or trim surrounding the active light collector surfaces, this creates dead-space. This dead-space can be minimized by overlapping the light collector rows slightly as in FIG. 9. FIG. 9c shows detail from 9b, showing light collector rows 150 that have a trim 166 composed of the aluminum frame 106 and the laminate surrounding the PV cells 104. The trim 166 of the lower light collector row 160 is positioned vertically beneath the trim 166 of the upper light collector row 158, shadowing the lower trim to incident light 164, and reducing the dead-space on the lower row 160. By slightly overlapping the light collector rows, the dead-space attributable to trim or framing around the light collector rows is reduced by almost one half, and the only light 168 that strikes the lower light collector rows 160 is striking light collector areas directly. In the case of FIG. 9 this is the PV cells 102.

Staggering the light collector rows in this way confers tremendous advantages to solar power systems, particularly to concentrated photovoltaic systems employing trackers. The remainder of this document will outline the areas in which advantages are conferred by the present invention, firstly in the ability of solar power systems to shed excess heat and secondly, in the reduction in wind resistance of the modules. Reductions in dead-space will also be highlighted throughout.

Additionally, the specific embodiments of this invention apply to the light-guide solar optic technology, as outlined in U.S. patent application Ser. No. 12/113,705.

The present invention is of relevance to any CPV system because CPV systems use trackers that must withstand wind loading and need to dissipate heat easily. The present invention can apply to situations where the modules are illuminated by light that has a normal angle of incidence in at least one plane; in other words the light travels perpendicular to the top surface of the module in at least one plane. This is the plane of the cross section shown in FIG. 9b. The present invention can apply to modules for use on dual axis trackers, when the light is always maintained normal, and to modules for use on single axis trackers when light is kept normal in one plane. When modules employing vertically staggered light collector rows are used with a single axis tracker, the rows are ideally parallel to the axis of the tracker.

The American Society for Testing and Materials defines the standard intensity of sunlight as 850 Watts per square meter for direct irradiance (sometimes called direct normal irradiance or DNI). These are approximations of the actual integrated power density for direct light under an air mass of 1.5 (AM1.5). This intensity level is referred to as one sun, which is the unit used to describe the concentration factor of a CPV system. The intensity of light at the PV cell is described in suns, so if the intensity of light at the PV cell is 85,000 Watts per square meter then the system is operating at 100 suns. Concentration factors of up to 10,000 suns are theoretically possible, but most state of the art systems employ concentration ratios that are lower, between 300 and 1400 suns.

Typical PV cell sizes for use in concentrator systems vary from around 1 cm by 1 cm to around 1 mm by 1 mm. For example, consider a system operating at 900 suns concentration using 3 mm by 3 mm cells. The area of the cells is 0.000009 square meters, and the power density at the cell is 765,000 Watts per square meter. The available power at the cell is 6.9 watts. Typical solar cells used in state of the art CPV modules have conversion efficiencies of around 37%, so of the 6.9 watts of power in the form of light at the cell, 2.6 watts will be converted into electricity and the remaining 4.4 watts will largely be converted to heat. A small percentage of light will also be lost due to scattering and Fresnel losses, but this is negligible in comparison to the amount of light that is converted to heat.

Over 4 watts of heat being dissipated from a 3 mm by 3 mm cell is a large amount of heat. If the cell were simply in room temperature air with no wind, with no connection to a heat sink, dissipating heat by convection and irradiation, the cell would heat up to over 1000 degrees Celsius. This could destroy the PV cell. In order to facilitate the transport of heat from the PV cells, the PV cells are often mounted onto a printed circuit board (PCB) that employs alumina or aluminum nitride as a substrate, but any electrically insulating, thermally conductive ceramic or other material would also work. The combination of the PV cell and the PCB is called a receiver.

Although only photovoltaics will be discussed in this document, any other device that converts light into useful energy could also be employed in place of a photovoltaic cell. Useful energy includes but is not limited to electricity, thermal energy, or kinetic energy. Photovoltaic cells are the most common form of device and will be used by way of example in this document, but all inventions in this document pertains to any other device for converting light to useable energy.

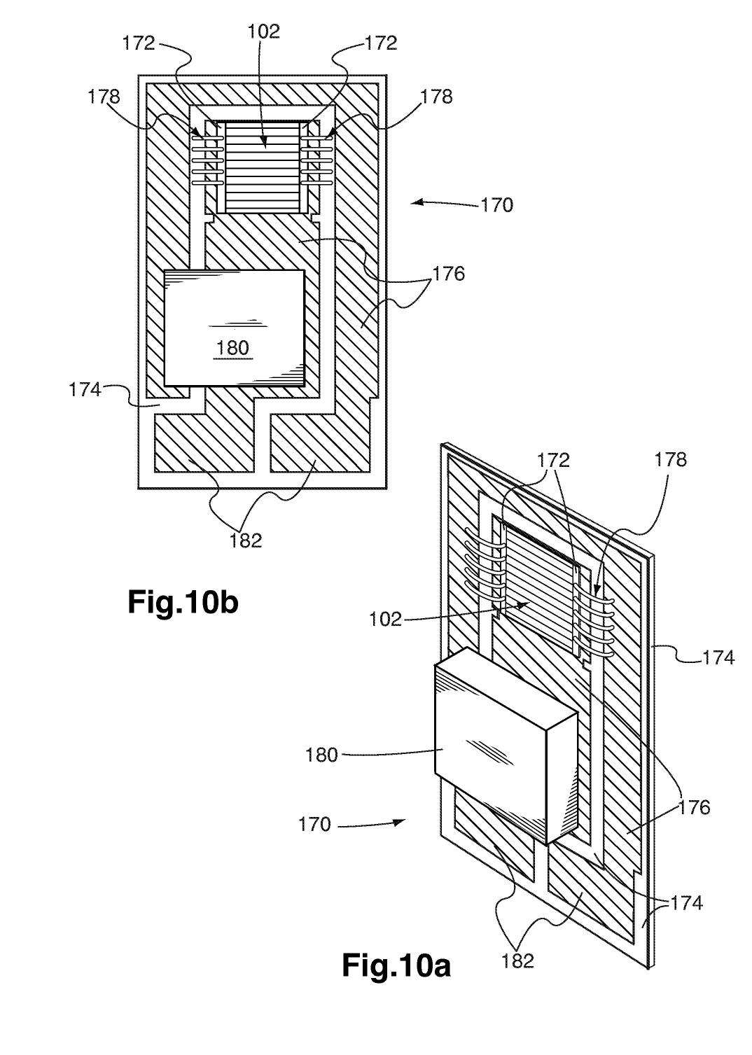

When the receiver uses photovoltaics, an important consideration is that the PCB substrate be thermally matched to the PV cell, so that stress is not induced in the delicate cell due to differences in expansion as the receiver heats and cools. The PCB has some sort of conductive metallization that enables the creation of the necessary circuit employing the PV cell. FIGS. 10a and 10b show an exemplary receiver assembly 170 that employs photovoltaics. The PV cell 102 has bus bars 172 on its top surface (the light receptive surface) and a metallization on its back side (not shown). The PCB is made out of a dielectric 174 like alumina, with a metallization pattern 176 on the top surface onto which the PV cell 102 is connected. The connection between the PCB and the backside of the PV cell is made either by soldering or by using a conductive epoxy. The front side bus bars 172 are connected to the PCB using either wire bonding 178 as shown, or another welding or soldering process. A bypass diode 180 can optionally be included on the receiver assembly. Solder pads 182 are used to connect this receiver to external circuits; typically in a module many such receivers are connected in series.

A receiver would also overheat if it was left floating in the air under concentrated sunlight, so it is generally connected to a heat sink of some description. The connection of the receiver to a heat sink can be made in such a way so as to enable the easy transfer of thermal energy out of the receiver and into the heat sink. This can be accomplished by way of thermally conductive epoxies, soldering, welding, thermal grease, or thermally conductive tape. The heat sink is often simply the structural enclosure that holds the module together.

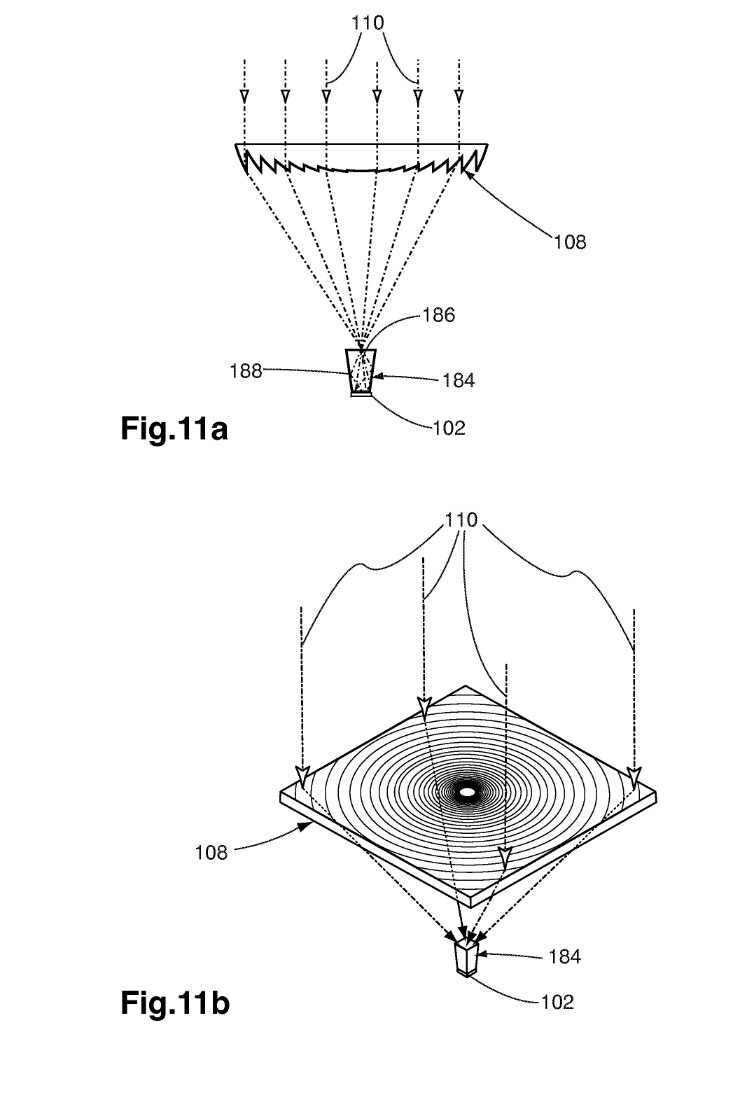

Some CPV systems employ a secondary optic, sometimes called a homogenizer, immediately prior to the PV cell. This optic is directly coupled to the PV cell using an optical epoxy, and serves the purpose of spreading the light out evenly before it reaches the PV cell. A secondary optic can also provide some further concentration. The optimal secondary optic from the perspective of enhancing concentration is called a Winston Cone, but more typically the secondary optic is a tapered optic with four flat sides. FIG. 11a shows a cross section of a design using a Fresnel lens and a secondary optic, and FIG. 11b shows an isometric view of the same design. Incident light 110 is concentrated by the Fresnel lens 108 onto the secondary optic 184. Light inside the secondary optic 186 experiences internal reflections 188, typically total internal reflections. One or more internal reflections can occur before the light reaches the PV cell 102 by way of an optical epoxy. The optical epoxy and the PCB to which the PV cell 102 would typically be connected are not shown.

The invention described herein applies to photovoltaic systems employing secondary optics and receivers or not, and wherever a PV cell 102 is indicated in the text or in a figure, it should be considered to be referring to all of the following: PV cells with a secondary optic and receiver, PV cells with a receiver and without a secondary optic, PV cells with a secondary optic and no receiver, and PV cells alone. In general, most CPV systems employ both secondary optics and receivers, and most ordinary PV system employ neither.

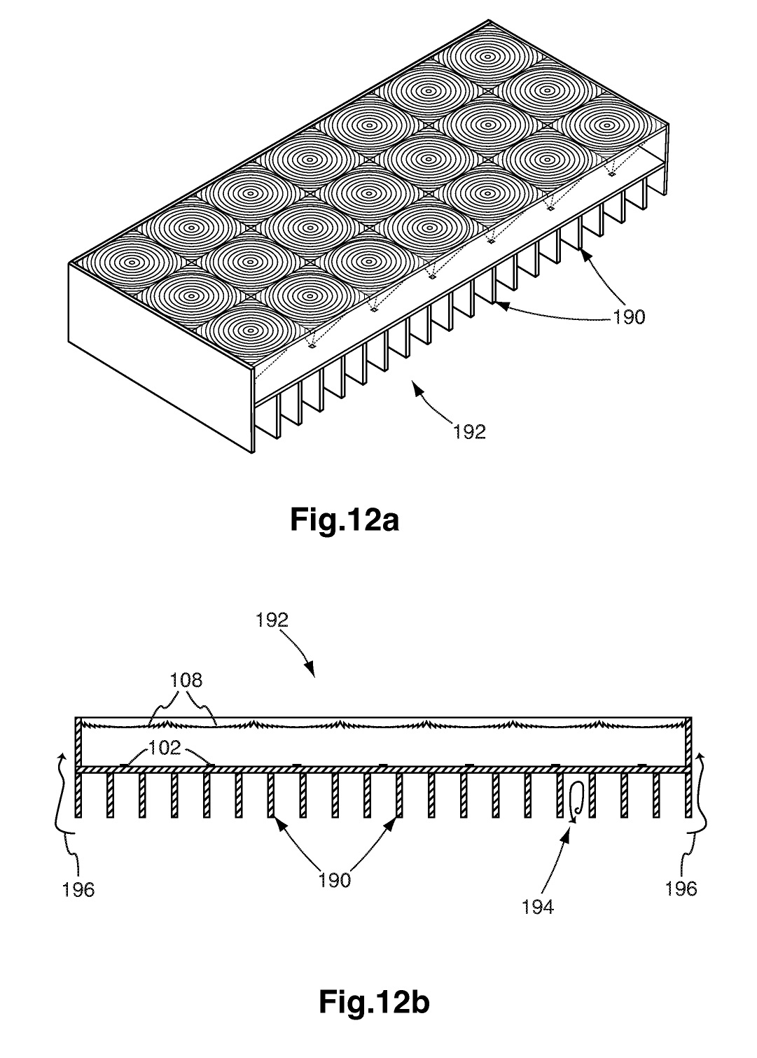

Many CPV makers place heat spreading fins on the bottom of the enclosure to increase the surface area over which heat can be exchanged with the air. FIG. 12 shows fins 190 added to the bottom of the Fresnel lens module 192. However, when the sun is directly overhead and the panels are facing straight up, the fins do little to improve heat dissipation. This is because hot air tends to rise, so it rises and becomes trapped between the fins. This results in recirculation of air as shown by the spiral 194. Hot air is only able to escape by flowing around the panel on both sides as shown with the line 196. Trapped air at the bottom of the module prevents it from cooling effectively. Removing the fins, while it does reduce trapping of heat, also reduces the area over which heat can be exchanged between the enclosure and the air.

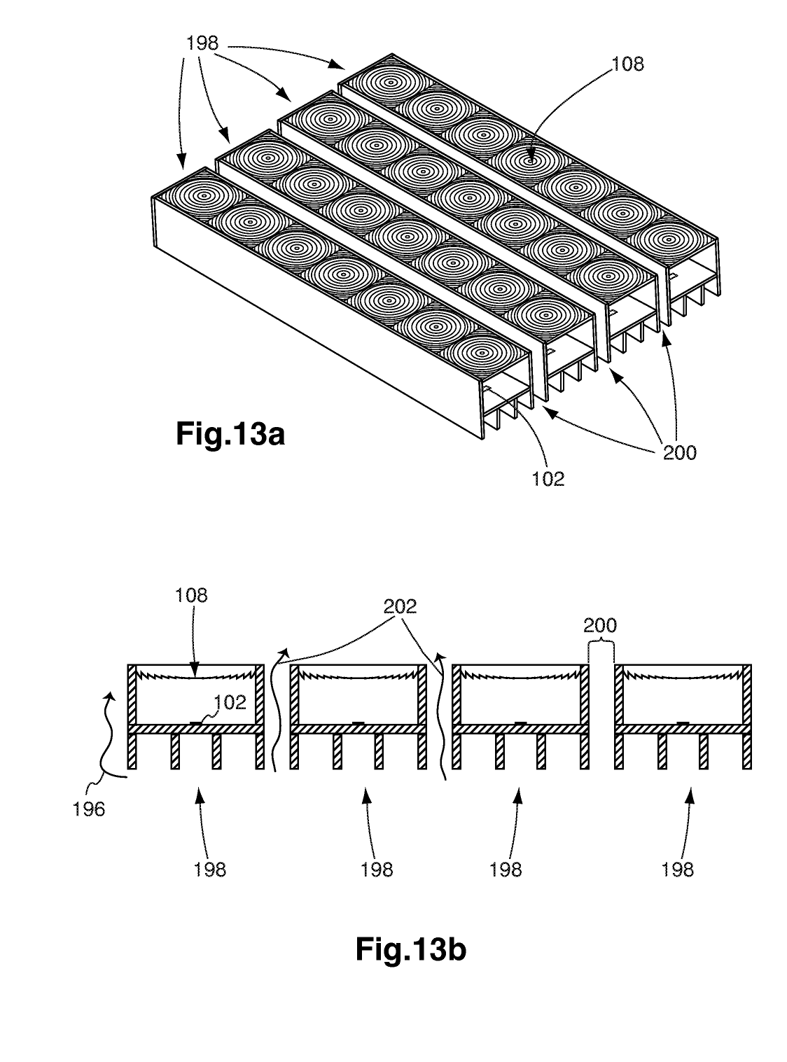

Breaking up the module, as shown in FIG. 13, into narrower rows of light collector modules 198 and leaving spaces 200 between the rows of light collector modules is one technique that can significantly improve heat shedding of the modules. Hot air 202 can rise between the rows of light collector modules as well as up on the outside the module 196. The disadvantage of the approach is that it creates dead-space between the light collector rows where no light is collected, reducing overall system efficiency.

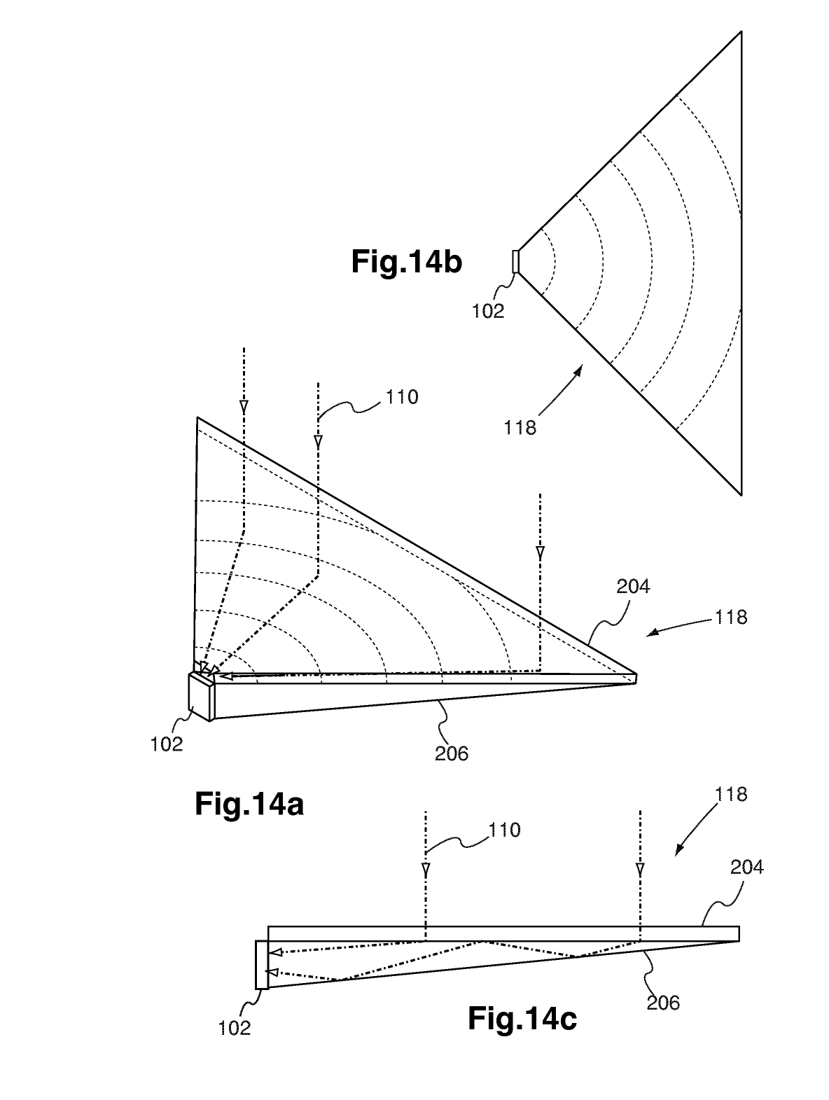

Light-guide solar optics, as described in U.S. patent application Ser. No. 12/113,705, function differently than Fresnel lenses, and as a result the modules have differences as well. The inner workings of light-guide solar optics will not be addressed here, but FIG. 14 shows the external effects of a light-guide solar optic 118, consisting of a deflecting layer 204 and a light-guide layer 206. FIG. 14a shows an isometric view of the optic 118, FIG. 14b shows a top down view of the optic 118, and FIG. 14c shows a side on view of the optic 118. Incident normal light 110 is concentrated and conducted (propagated) inside the light-guide solar optic 110 to a PV cell 102. The concentrated light has much more intensity per unit area that the incident light 110.

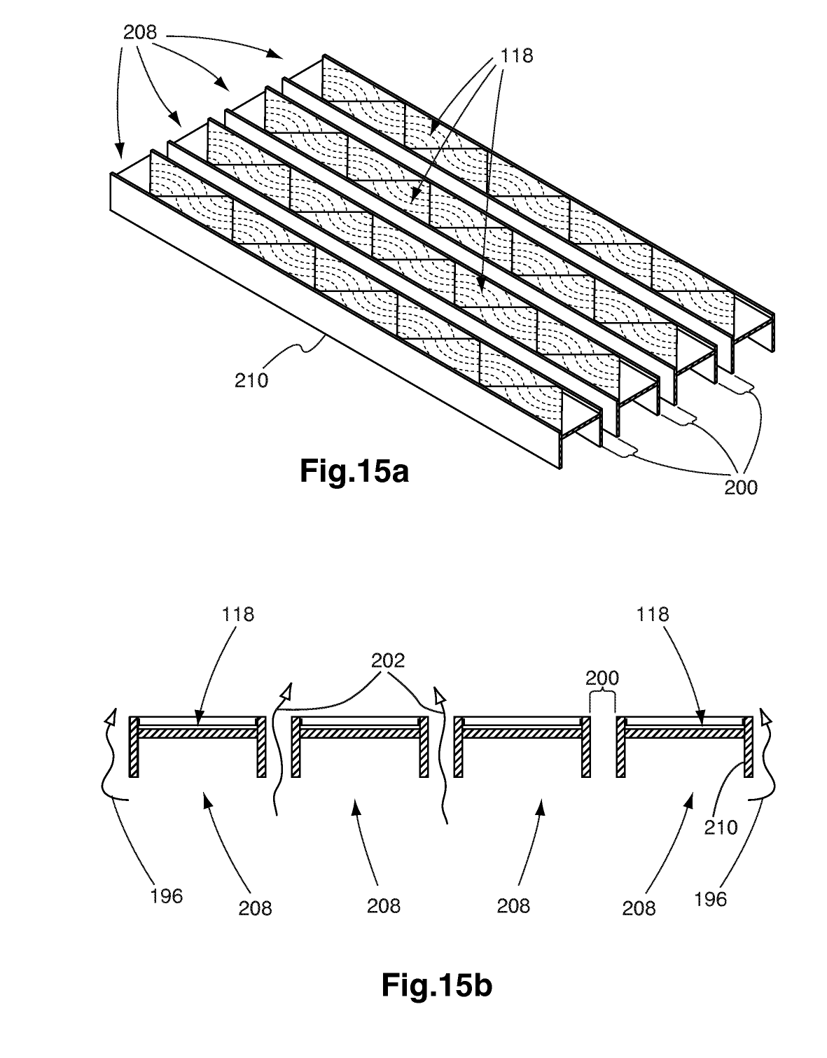

Because the PV cells are on the edge of the optics rather than underneath the optic, the enclosure is considerably shallower than a system employing a Fresnel lens. FIG. 15a shows an isometric view of several light collector rows 208 of light-guide solar optics 118 arranged with gaps 200 in between the rows. FIG. 15b shows a cut through view of the light-guide based light collector rows 208 arranged with gaps 200 between them. The aluminum profile supporting the optics 210 is shown as well. As with the Fresnel lens-based system from FIG. 13, hot air can rise between the rows 208 as shown with the arrow 202 and hot air can escape around the modules as shown by the arrow 196.

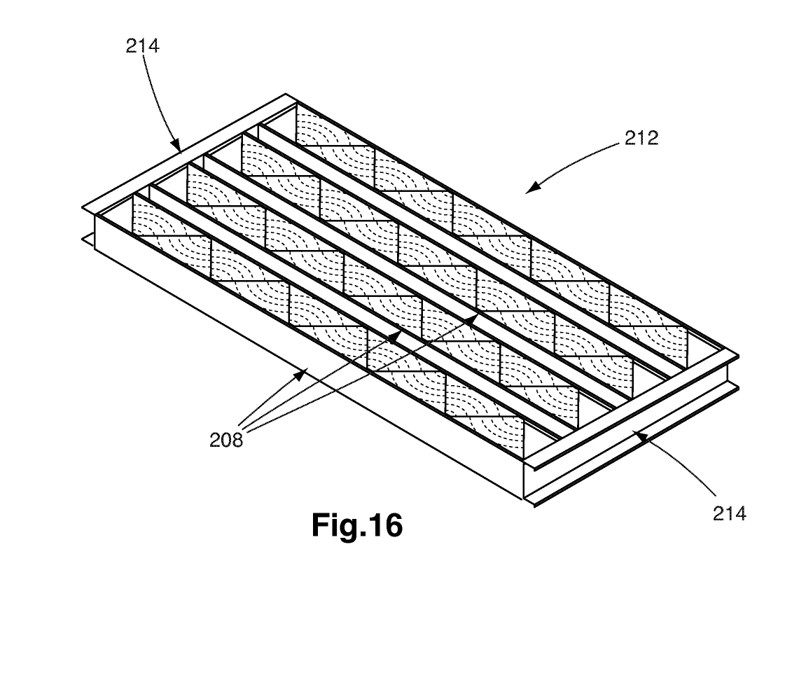

FIG. 16 shows a module 212 from made rows 208 arranged as in FIG. 15. The rows 208 are each attached at the ends to aluminum “C” end caps 214, which can be referred to as supports. Any other suitable structural elements can be used in order to hold the light collector rows 208 together without departing from the scope of the present disclosure.

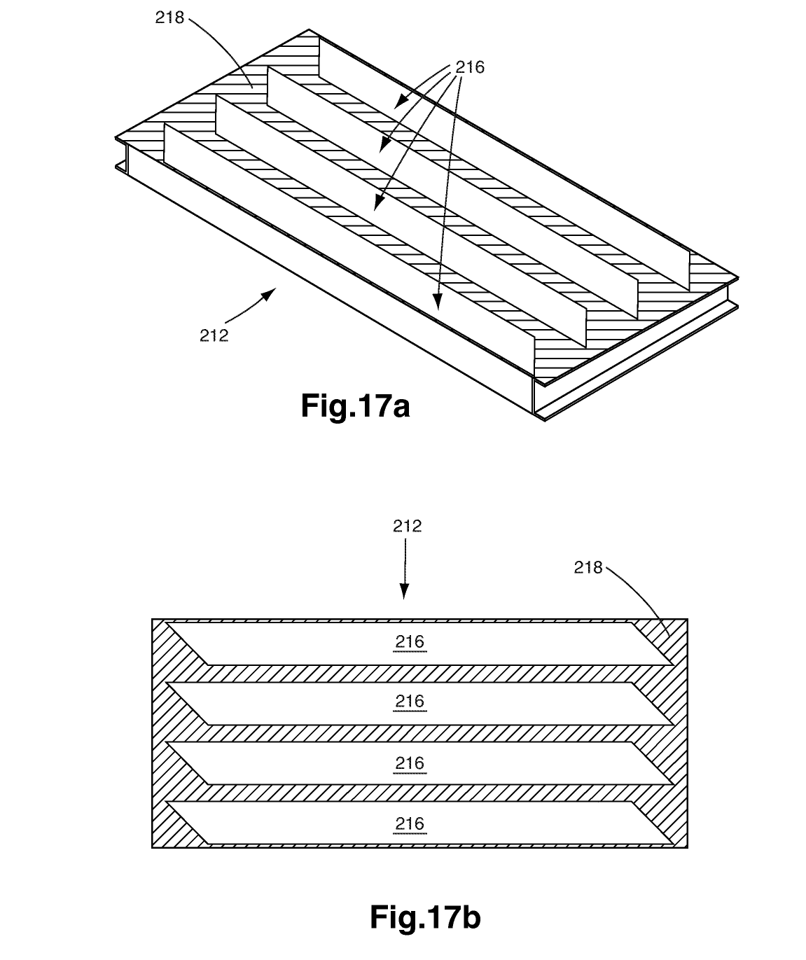

While making a module with small spaces between light collector rows creates a module with good thermal shedding characteristics, it creates a significant amount of unnecessary dead-space. FIG. 17 shows a graphical breakdown of the dead-space associated with the module 212 from FIG. 16. FIG. 17a shows in isometric, and FIG. 17b shows a top down view of the module 212. The light collecting areas 216 are depicted as solid black areas and the hashed out area 218 is the dead-space. Dead-space consists of any trim or frame around the optics and any spaces between the rows. In the example shown, around 60% of the modules surface is collector area, and 40% is dead-space. This is exaggerated for the purposes of explanation; practical numbers for dead-space on real modules would range between 5%-25%. For modules that do not leave gaps or spaces within the structure of the module itself for heat to escape, gaps are often needed between the modules when they are being installed in an array on the tracker. In these cases, gaps between the modules serve the same air transmittance role that gaps within the modules serve, and will create dead-space in the system between the modules and amounts to the same thing.

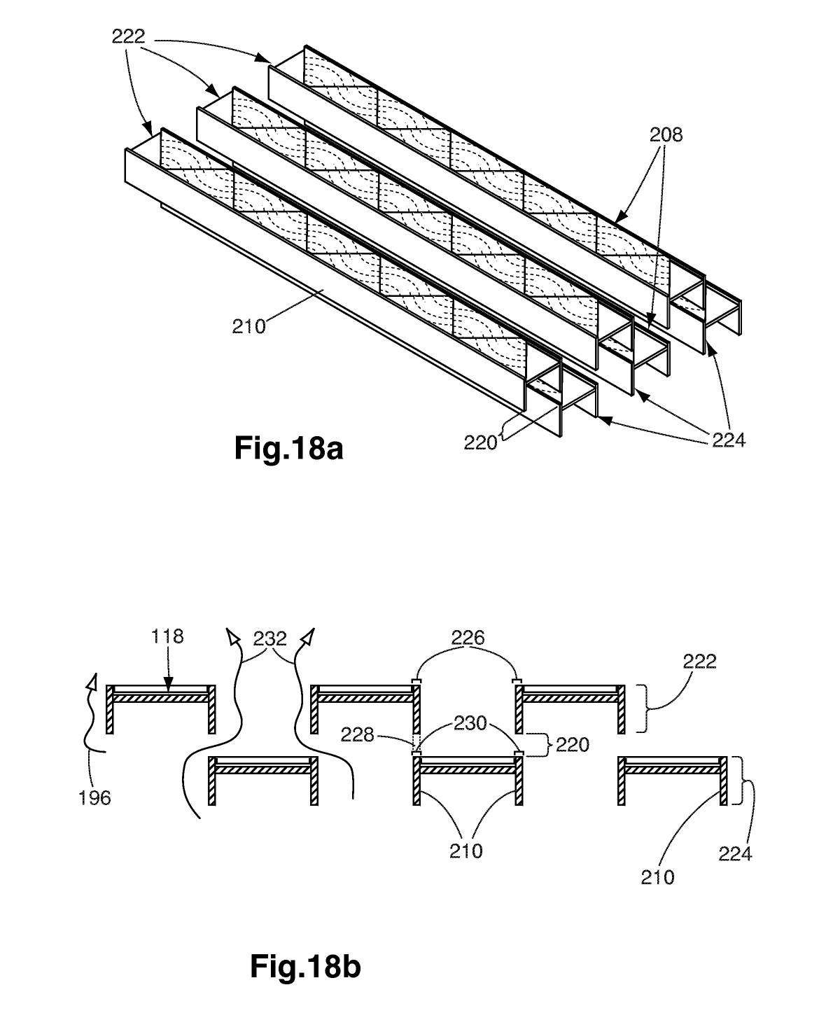

Staggering the light collector rows vertically provides gaps without increasing the dead-space on the module. FIG. 18 shows an arrangement of the rows 208 from FIG. 17 with staggering. As shown at FIG. 18b, gaps 220, which can also be referred to as air gaps, are left vertically between the upper rows 222 and the lower rows 224. The upper rows 222 form a first group of solar energy collector modules and the lower rows from a second group of solar energy collector modules. The upper rows 222 and the lower rows 224 are staggered with respect to each other such that they overlap slightly so that the portion of the aluminum structural elements 226 adjacent the light collectors (previously referred to as the “trim” around the light collectors) of the upper light collector rows 222 cast a shadow 228 on the trim 230 of the lower light collector rows 224. This prevents sunlight from striking the structural aluminum elements 210 on the bottom rows 224, reducing the dead-space that would otherwise have been occupied by these structural elements. The vertical gaps 220 allow hot air to rise 232 between the rows as well as for air to flow around 196 the outside of the module.

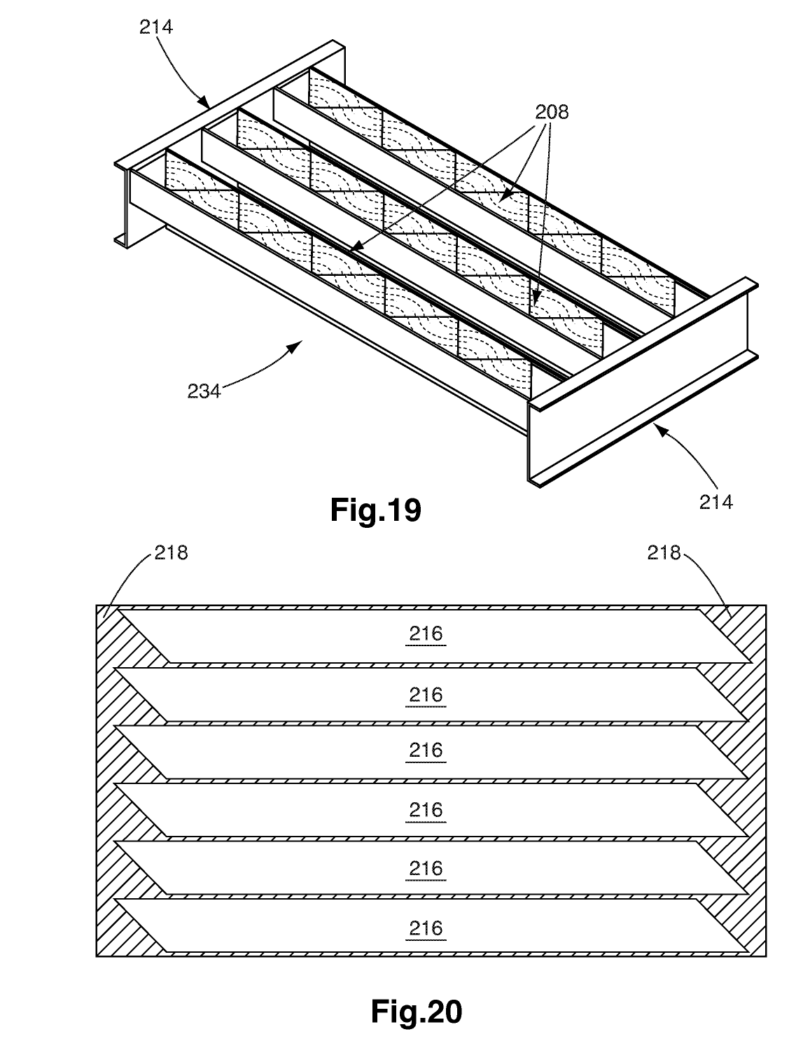

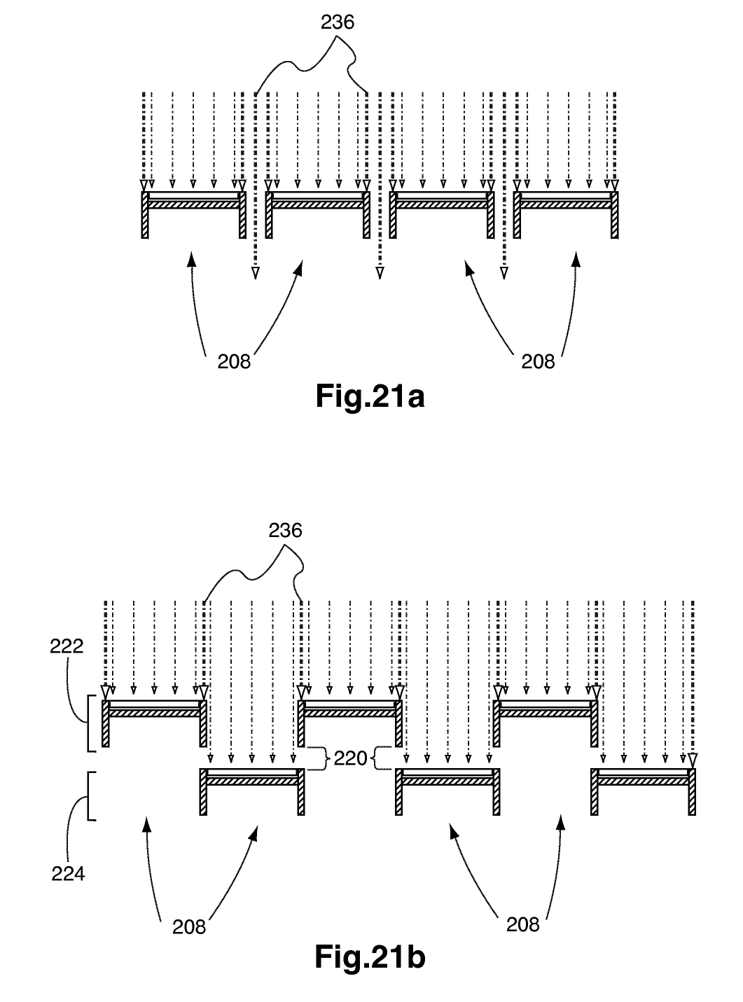

FIG. 19 shows one way that the staggered light collector rows 208 can be arranged into a module 234 using end caps 214, which can also be referred to as supports. The end caps 214 need to be made taller to accommodate the vertical staggering, but that is the only change in terms of design. The amount of dead-space in this design is significantly reduced. FIG. 20 shows the dead-space 218 versus collector area 216 which is achieved with this design. In the figure, almost 80% of the module area is collector surface, and only 20% is dead-space. If light collector rows are made longer and the end caps narrower, the collector surface could occupy as much as 95% of the module area. FIGS. 21a and 21b shows a side-by-side comparison between horizontal spacing of the light collector rows 208 and vertical staggering in terms of lost light. The bold lines 236 indicate light that misses the light collector areas.

The size of the vertical gap 220 between the upper rows 222 and the lower rows 224 has not been specified thus far. The gap size employed in all the figures is roughly 30% the light collector row width; however, any other suitable gap size can be used without departing from the scope of the present disclosure. If the rows were 10 centimeters wide, then the gap size would be shown as approximately 30 millimeters. Smaller gaps will also work, and internal research has shown than gaps as small as 6%-10% of the light collector row width would function well from a heat shedding perspective. Very large gaps lead to bulky designs and have little advantage in terms of heat shedding. However, gaps of any suitable size can be used and, it is not necessary for the gaps to all have the same size.

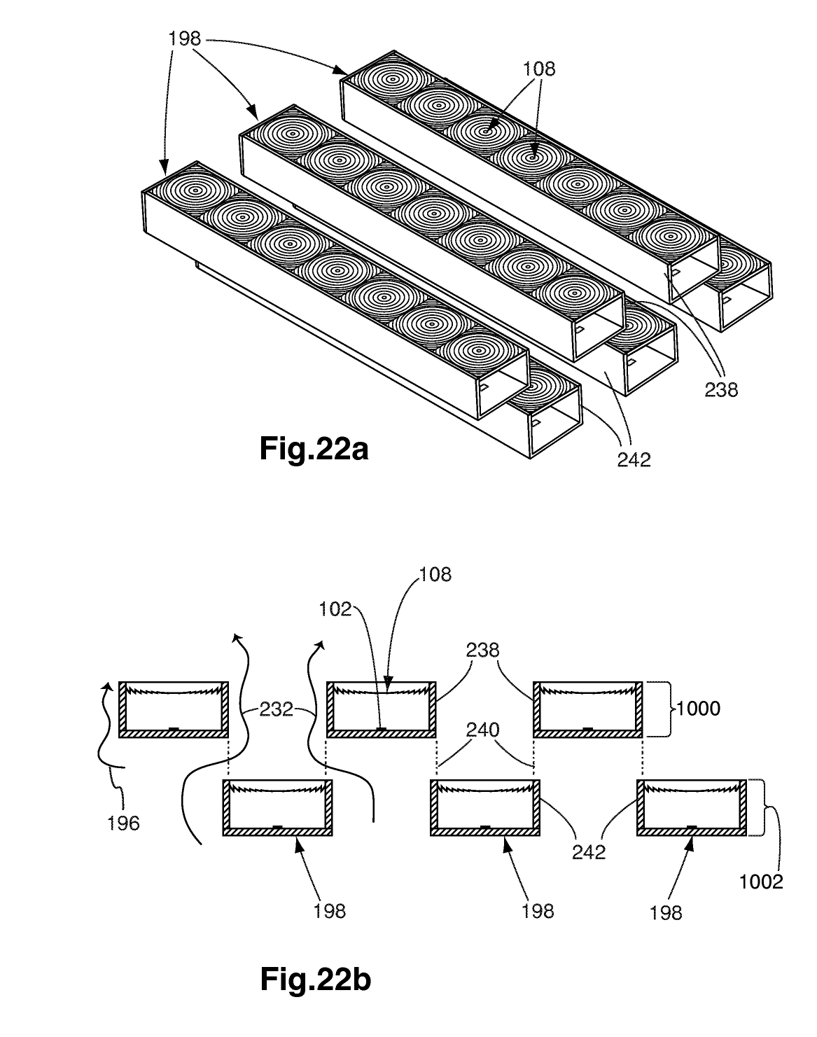

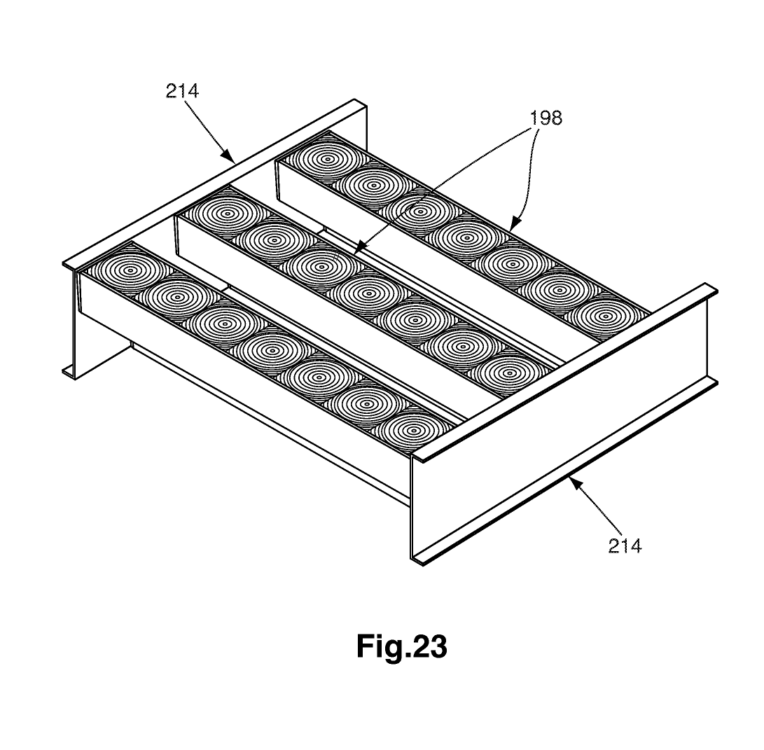

The staggering between two groups of solar energy collector modules also reduces the dead-space in modules employing Fresnel lenses. FIGS. 22a and 22b shows light collector rows 198 of a Fresnel lens based system arranged in a vertical staggering mode. Heat can rise 232 between the light collector rows as well as around the outside 196. The light collector rows 198 are drawn without fins but could have fins as well. A first group 1000 of solar light collector modules and a second group 1002 of solar light collector modules are shown at FIG. 22b. The enclosure 238 of the upper light collector rows shadows 240 the enclosure 242 of the lower light collector rows. FIG. 23 shows the rows 198 assembled module using end caps 214, which can also be referred to as supports. The above-noted staggering between two groups of solar energy collector modules extends the same thermal dissipation advantaged to any Fresnel lens-based system, or any other CPV system.

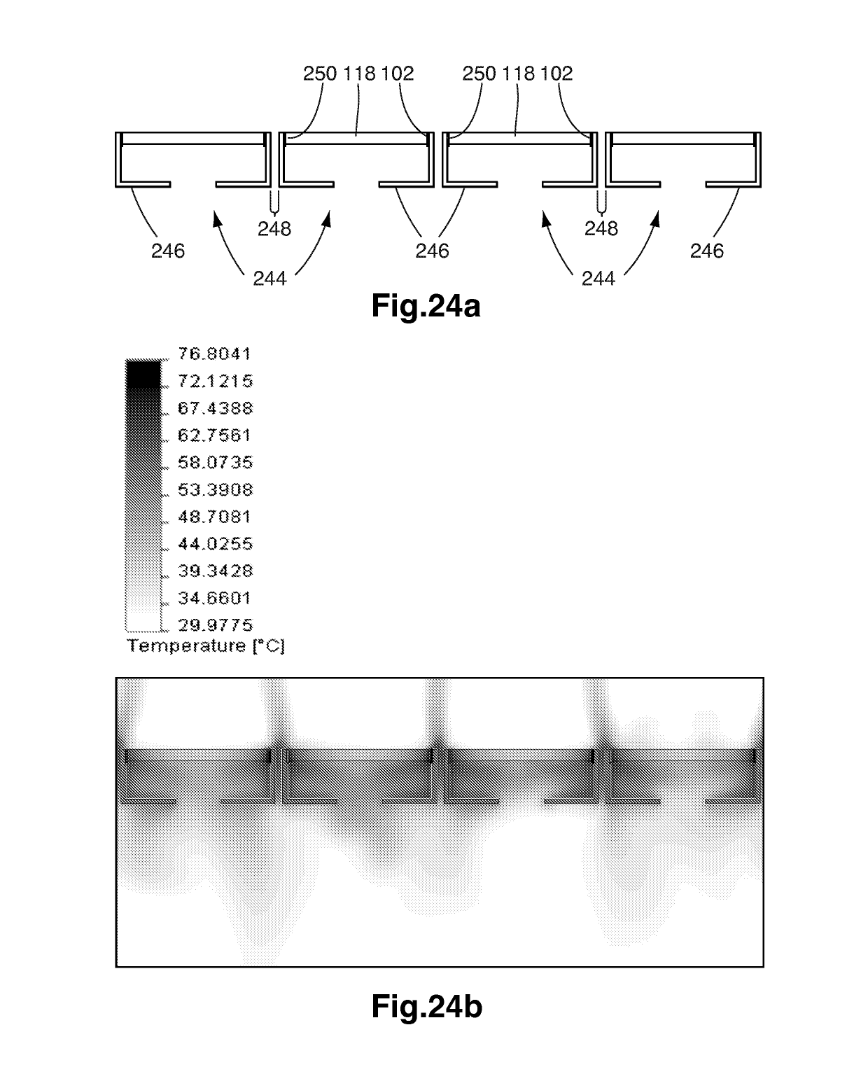

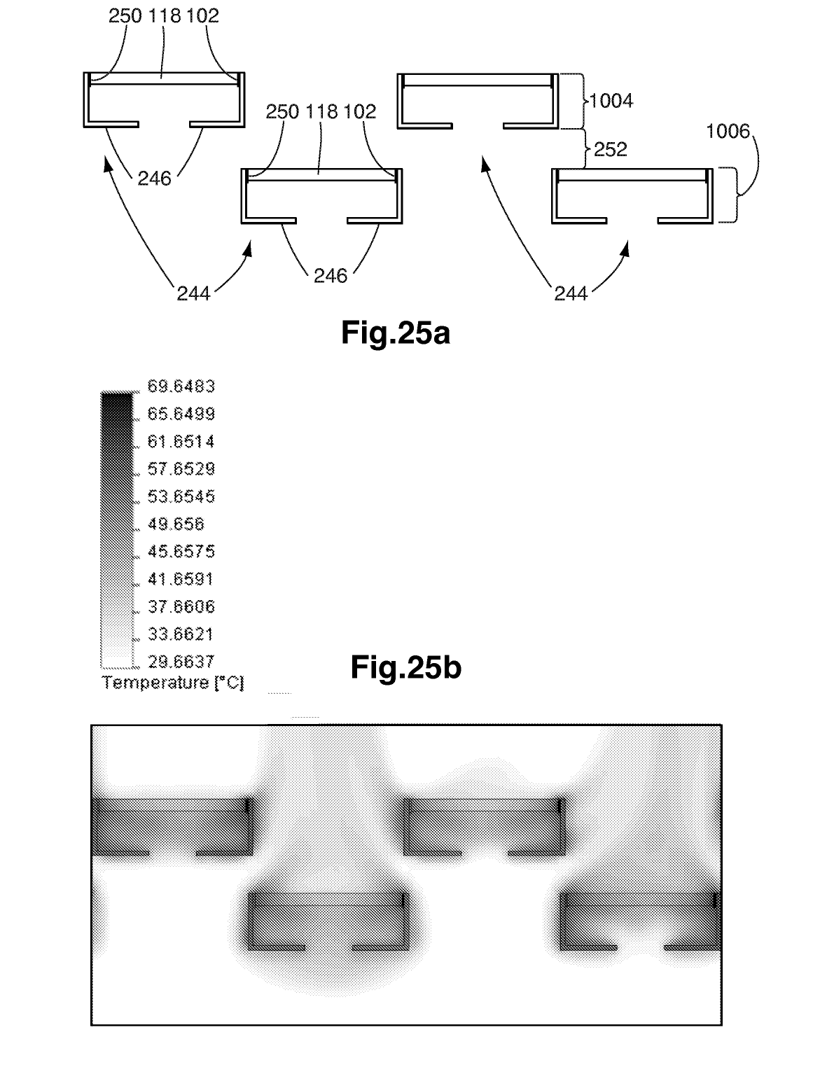

FIGS. 24 and 25 show thermal models made using computations fluid dynamics (CFD) using the software COSMOSFIoWorks by Dassault Systemes S.A., showing two solar modules under identical conditions. FIG. 24a shows a cross section through a solar module consisting of light collector rows 244 made of light-guide solar optics 118, PV cells 102 and aluminum structural elements 246 spaced with 4 mm gaps 248. Also shown are elements of structural adhesives 250. The rows 244 are effectively identical to the light collector rows 208 from FIGS. 15, 16, 18, 19 and 21 except that the supporting structure is made of two “L” shaped pieces of aluminum and not one solid piece. FIG. 24b shows the results of a computational fluid dynamics study, where the color in the figure indicates temperature. The simulations are under the following conditions: 30 degrees Celsius ambient temperature, no wind, and 0% humidity in the air. The simulation assumed 850 Watts per square meter DNI incident onto light-guide solar optics, each with top surface areas of 0.011 square meters, concentrating that light onto small PV cells with areas of 0.00003 square meters. The light collector row was assumed to be 1.6 meters long and 10 cm wide, consisting of 15 optics and PV cells. The loss of light in the optics due to scattering and absorption was assumed to be 25%, so the concentration at the PV cells was approximately 275 suns. The total optical power coupled to each PV cell is 7 watts, of which 30% was assumed to be converted into electricity. Approximately 5 watts of power was assumed to be converted to heat at each of the cells. This heat was then conducted through PCBs made of alumina to aluminum structural elements that shed the heat into the air. The connections between the PCB and the PV cells was modeled to be a solder joint, and the connection between the PCB and the aluminum was modeled to be a thermal adhesive. Gaps 248 of 4 mm were left between the structural aluminum “L” pieces 246. The “L” pieces 246 were 3 mm thick. The maximum temperature in the model, at the PV cell itself, reached 76.8 degrees Celsius.

FIG. 25a shows a cross section through another module consisting of the exact same light collector rows 180 as FIG. 24. The light collector rows are staggered, with vertical gaps 252 instead of horizontal gaps. A first group 1004 of solar energy collector modules and a second group 1006 of solar energy collector modules are shown at FIG. 25a. The top light collector rows structural “L” pieces 246 overlap those of the lower light collector row, so there is less dead-space in the configuration. The vertical gap 252 was approximately 40 mm. Under the exact same condition as in the model shown in FIG. 24, the maximum cell temperature reached was only 69.6 degrees, so the cells stayed over 7 degrees cooler due to the improved heat shedding gained by staggering the light collector rows vertically. In addition, the dead-space due to the horizontal gaps 248 and the “L” pieces 246 on the lower light collector rows was eliminated. The light collector rows could have been spaced horizontally by 40 mm to achieve the same results thermally but this would increase the dead-space considerably. Systems based on other optics, such as a Fresnel lens based CPV system, would achieve similar gains in heat shedding capacity. FIG. 25b shows a computational fluid dynamics thermal model of the light-guide solar optic based module of FIG. 25a;

Another advantage to staggering the light collector rows is that it substantially reduces the wind loading on solar modules. CPV modules are mounted on trackers, and the trackers can accurately orient the CPV modules to face the sun. Wind loading can cause flex in the tracker and misalign the CPV modules. Wind loading also stresses the motors used to maintain alignment, and can cause large vibrations which can lead to structural damage of the tracker. To counteract this, trackers are made very stiff, which has high costs in terms of steel. By vertically staggering light collector rows in a CPV module, the forces due to wind on the modules and therefore on the tracker can be cut in half. By substantially reducing the forces caused by the wind, the tracker frame can be made less stiff, which requires less steel and thus costs less.

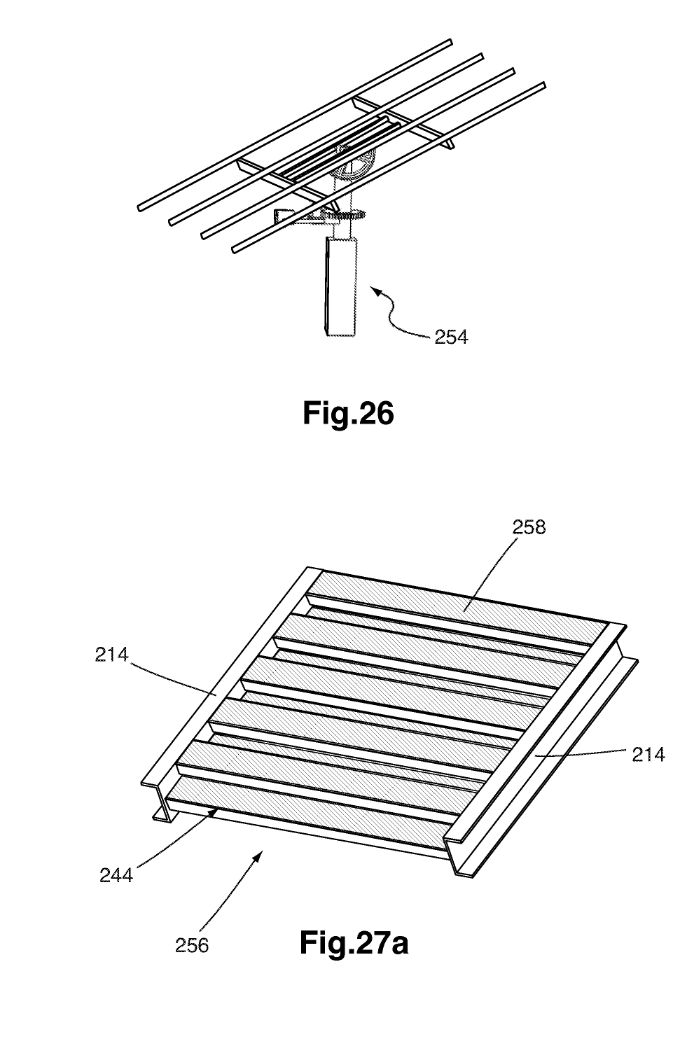

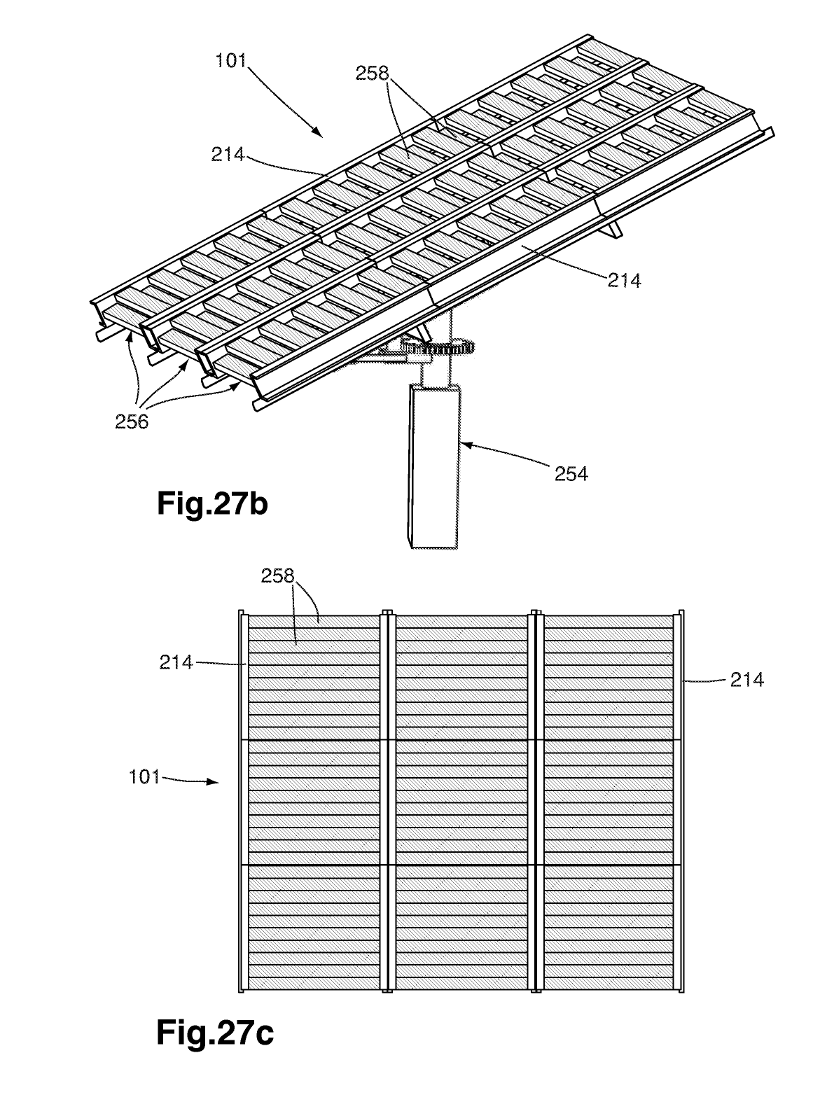

FIG. 26 shows a tracker 254 without solar modules. FIG. 27a shows a solar unit 256 that is made of light collector rows 244 arranged in a staggered arrangement. The unit 256 is different from the module 234 in that there are 10 light collector rows instead of 6, and the light collector rows are 10 centimeters wide by 1 meter long. The light collector surfaces 258 are filled in with hash marks. FIG. 27b shows a solar tracking system 101 that includes the tracker 254 covered with nine of the modules 256. FIG. 27c shows a head-on view of the unit 256 on the tracker (hidden in this perspective). The light collector surface 258 is filled with hash marks, showing very little dead-space. Although not shown in detail at FIG. 27b, the end caps 214, which can also be referred to as supports, are connected to the tracker 254 such that the tracker can orient the end caps 214, and the groups of solar energy collector modules secured thereto, to face the sun. The end caps 214 can be connected to the tracker 254 through any suitable means such as, for example, adhesives, fasteners and interlinking members.

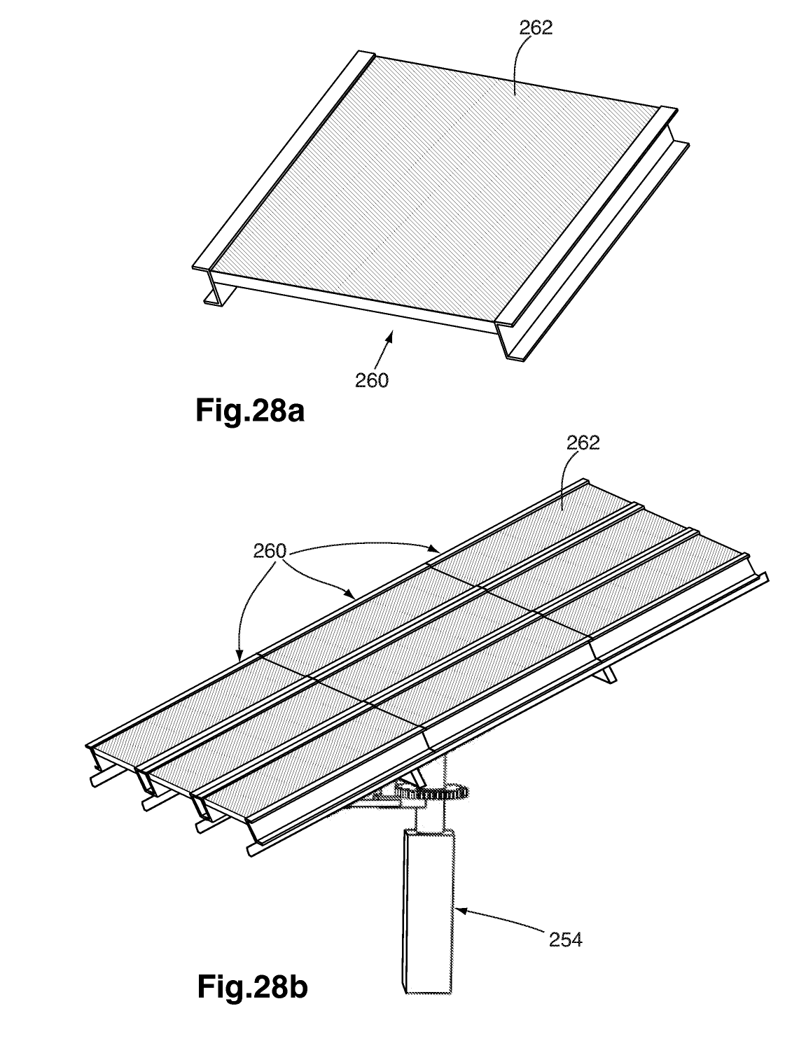

FIG. 28a shows a flat solar panel 260 that is one meter by one meter, which are the same dimensions as the unit 256. The flat panels 260 create a large unbroken area 262 which can act like a sail and react to high winds. The broken surface of the unit 256 containing staggered light collector rows 244 allows the wind to pass through the surface and thus does not act like a sail. The tracker 254 is only nine square meters in surface area; this is small but is shown as a demonstration. Normal trackers used in solar farms—such as those made by the company Titan Trackers of Spain—have two hundred square meters of surface area for modules.

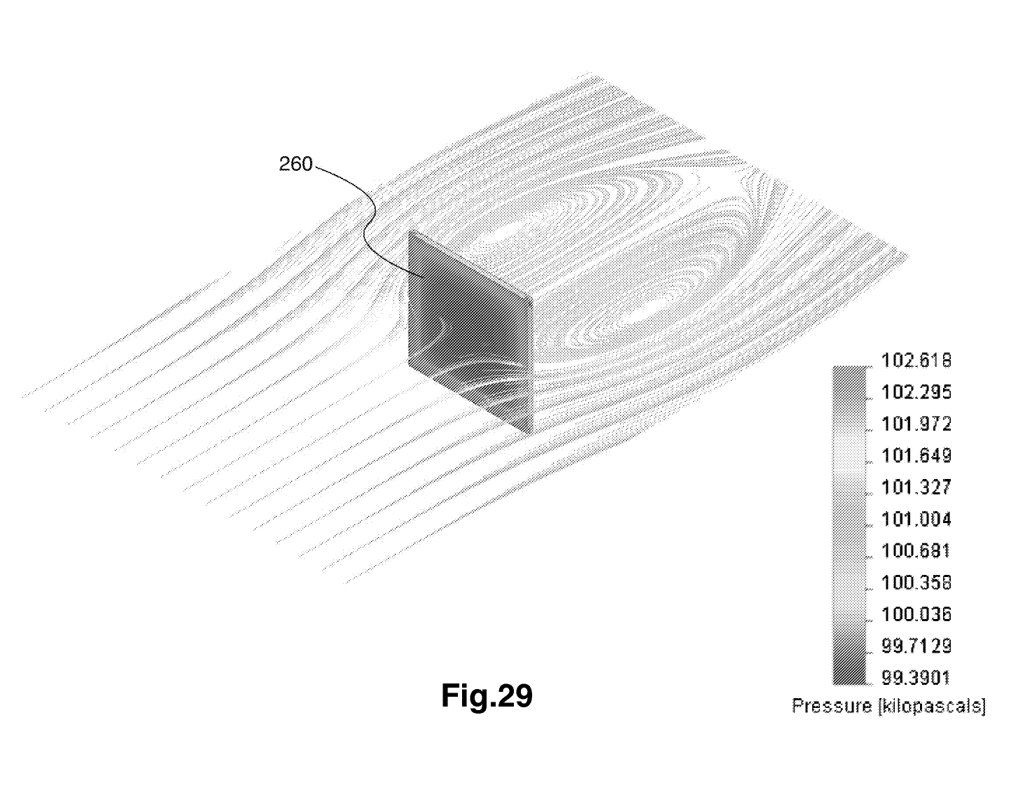

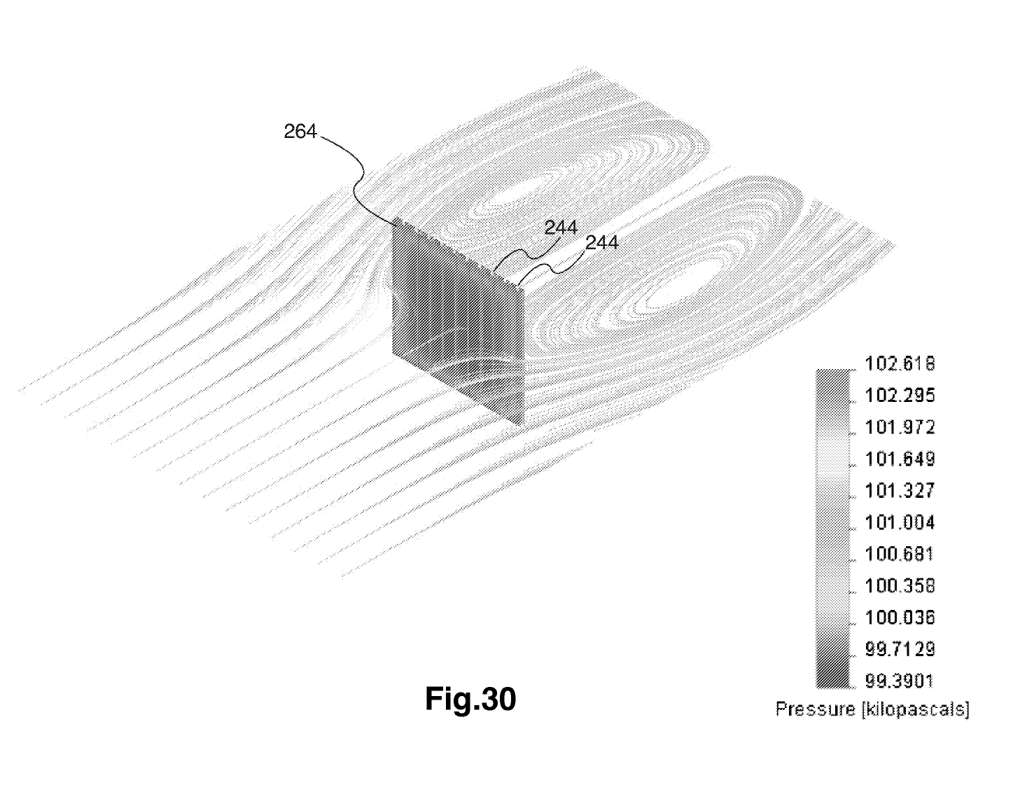

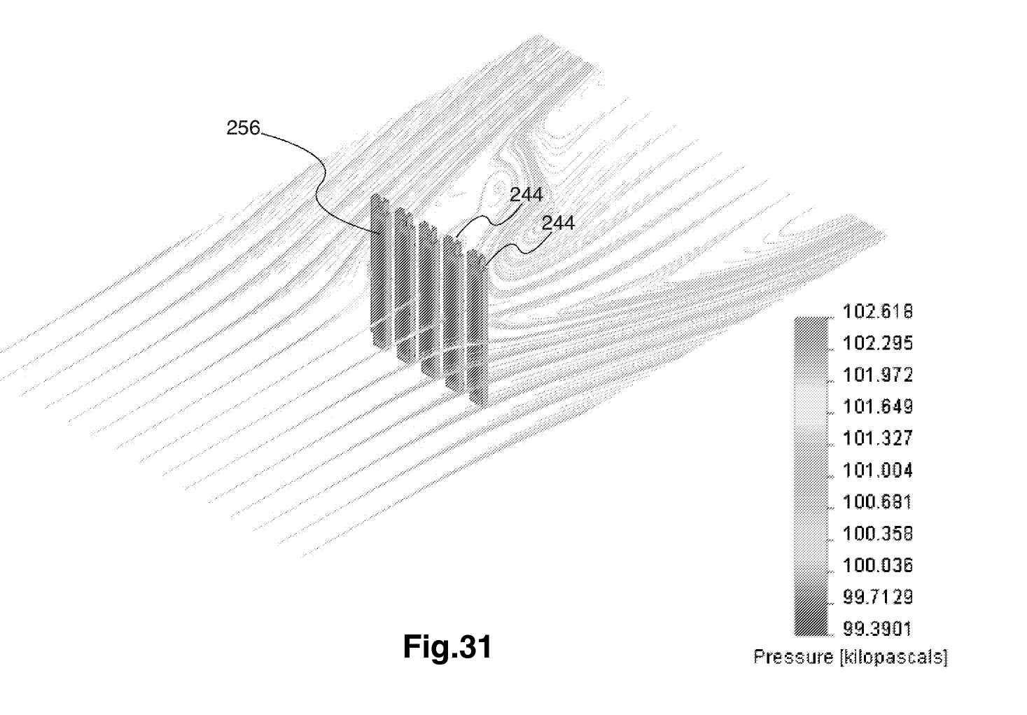

FIG. 29 shows streamlines from 20 meter per second wind incident on a square panel 260 one meter by one meter. FIG. 30 shows streamlines from 20 meter per second wind on a module 264 made of spaced but not staggered light collector rows 244, each row is 10 centimeters wide by one meter long, and there are ten light collector rows in the module with 4 millimeter gaps in between them. FIG. 31 shows streamlines from 20 meter per second wind on the unit 256 with ten light collector rows 244 arranged vertically staggered. The gray scale coding on the streamlines in FIGS. 29, 30 and 31 indicates the air pressure along the streamlines and on surfaces. The gaps between the light collector rows on the module 264 in FIG. 30 are too small to appreciably alter the airflow and barely disrupt the pattern in the streamlines compared to a solid square panel 260 from FIG. 29. By contrast, the unit 256 with staggered light collector rows 244 completely alters the airflow and results in a very different streamline pattern.

While comparing the streamlines and forces on an individual module gives some indication of the advantages of staggering light collector rows versus solid construction of solar modules, the advantages are increased even further when one considers the surface areas of trackers. Trackers combine dozens of modules to cover between 20 and 200 square meters. For the purpose of analysis, a 10 meter by 10 meter area of panels was modeled using computational fluid dynamics under 20 meter per second wind. Models were created for solid panels with six-millimeter gaps in between the panels and for modules made of staggered light collector rows. The one hundred square meter array of solid panels, 1 meter by 1 meter with quarter inch gaps, experienced a force due to the wind of 49,000 Newtons. In contrast, the one hundred square meter arrays of modules made of staggered light collector rows experiences a force due to the wind of only 18,000 Newtons. This enormous difference in wind loading will enable the construction of much less bulky tracking systems.

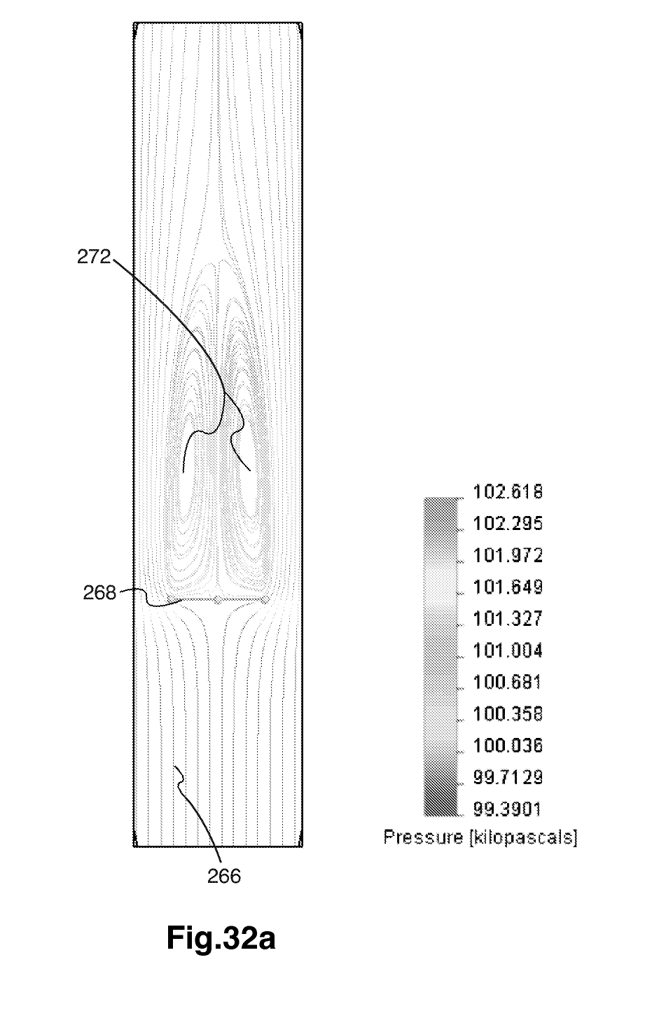

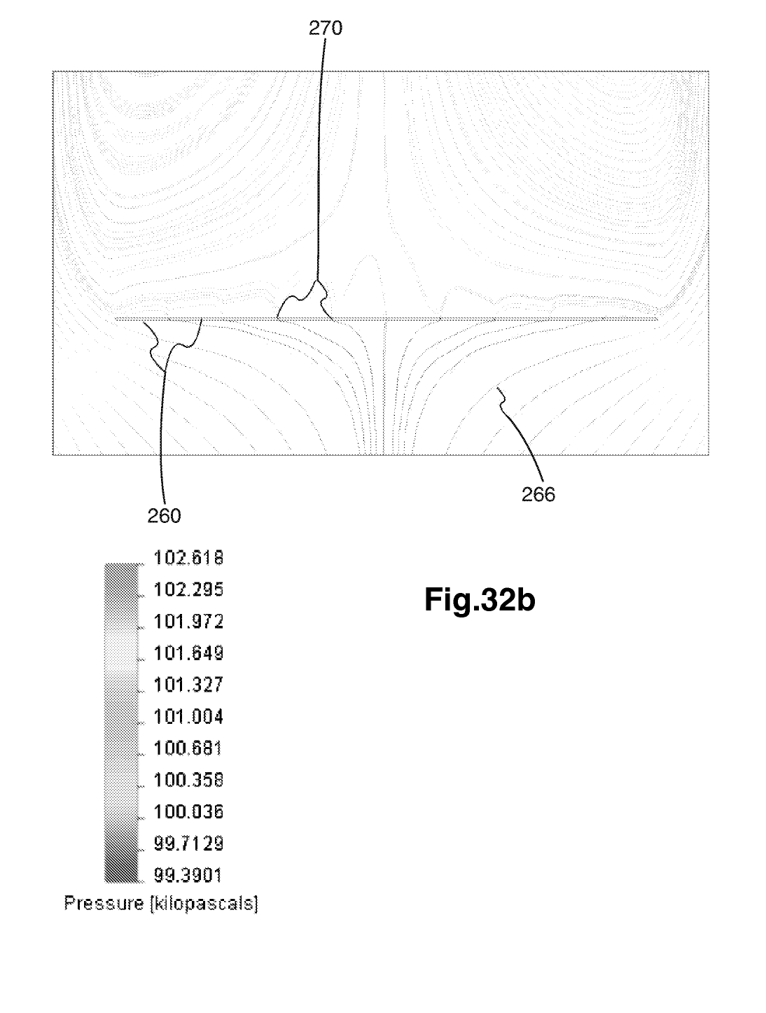

FIG. 32 shows streamlines 266 through a cut-away view on a 10 meter by 10 meter array 268 of solid 1 meter by 1 meter panels 260 with small gaps in between them. FIG. 32a shows a view zoomed-out, with the streamlines 266 and the array 268. FIG. 32b shows a zoomed-in view, again showing streamlines 266 and the array 268. The small gaps 270 between the panels 260 have some effect on the streamlines 270, but the wind largely circles around the array and creates a large vortex 272 behind the array. The gray scale coding on the streamlines indicates pressure as shown in the legend.

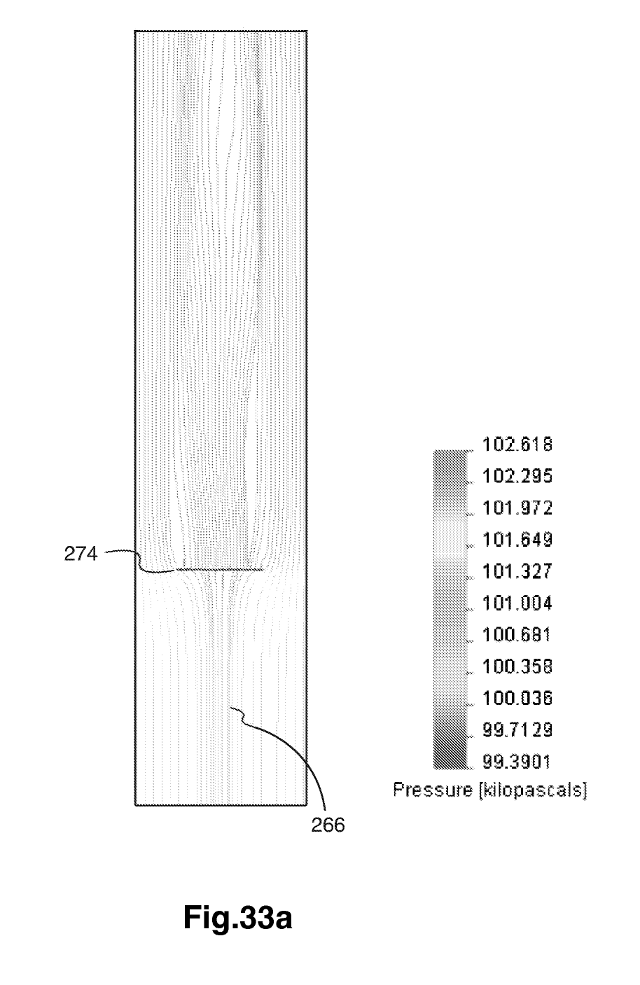

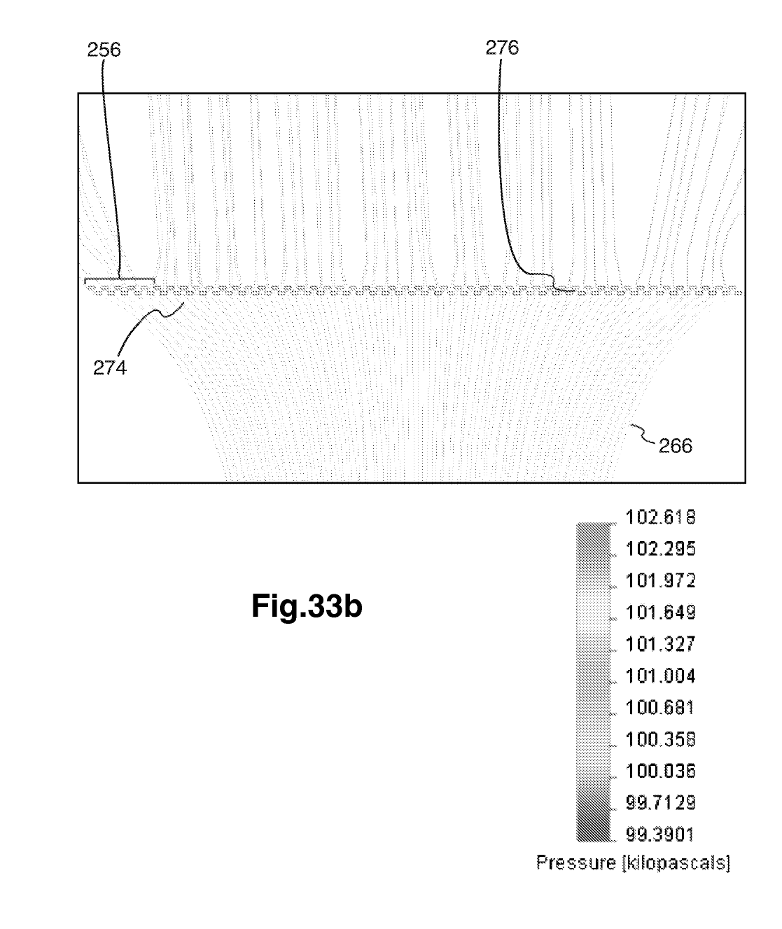

FIG. 33 shows streamlines through a cut-away view on a 10 meter by 10 meter array 274 of units 256, each 1 meter by 1 meter and made by staggering 10 cm wide light collector rows roughly 40 mm apart. These are the same as the units 256 shown in FIG. 31. FIG. 33a shows a view zoomed-out, with the array 274 and the streamlines 266. FIG. 33b shows a zoomed-in view, again showing streamlines 266 and the array 274. The large vertical 276 spacing left by staggering the light collector rows enables for the wind to move through the array 278 with little interruption. The wind is distorted but no vortex is formed. Small vortexes can form behind individual light collector rows, but the total forces due to the wind on the array is substantially reduced.

Staggered light collector rows enable modules that have better heat shedding and far less wind resistance. The light collector rows can be overlapped slightly to cut down on dead-space associated with the structural components of the module. It is also possible to make a tracker that staggers flat plate modules, shifting the burden of achieving the staggering to the tracker frame instead of the module structure. This is the same as staggering light collector rows within a module, except that whole modules tend to be around 1 meter across and therefore the benefits will be less.

Because staggering of light collector rows in a module increases the thickness of a module, it is particularly well suited to light-guide solar modules. This is because, unlike Fresnel lens based systems, light-guide solar modules are very thin to begin with. As such, the final thickness of the module is still less than most CPV modules, around 10 cm thick.

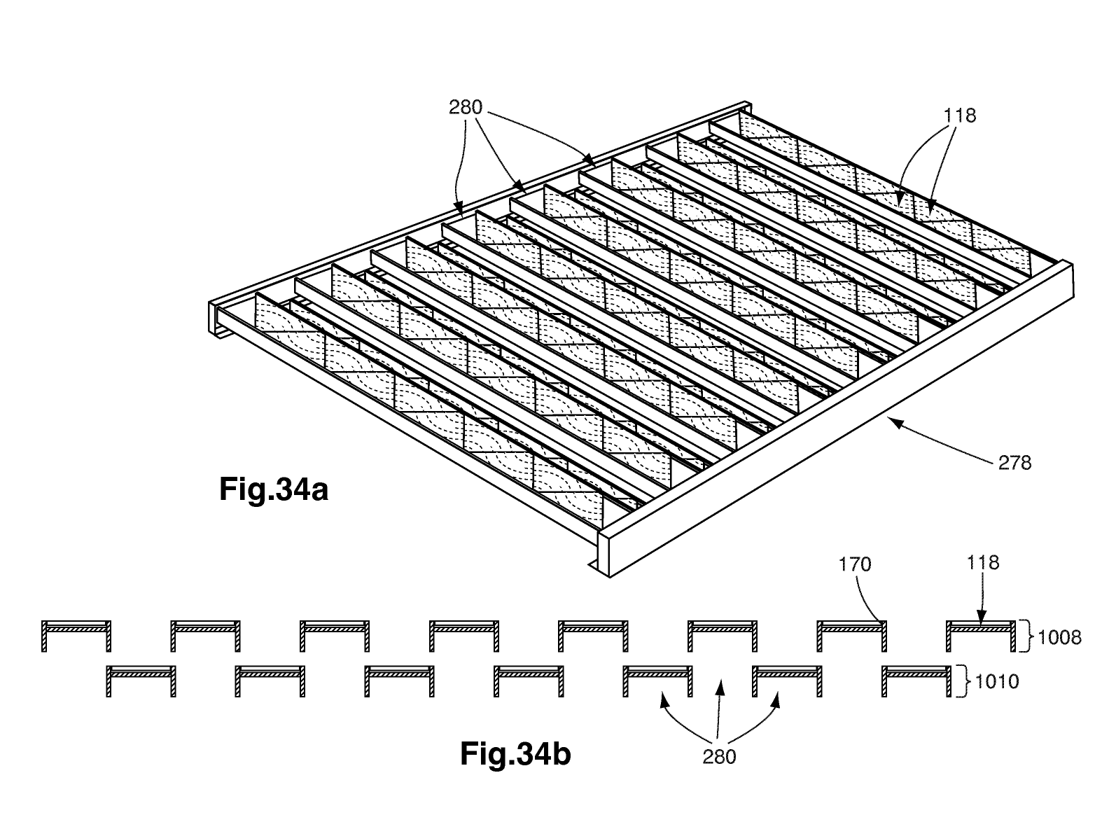

FIG. 34 shows an embodiment of a light-guide solar module 278 built using staggering of groups of solar energy collector modules. The light collector rows 280 each contain 15 optics 118 and PV cells receiver assemblies 170, and are 10.5 centimeters wide by 3.3 centimeters tall by 1.5 meters long. There are 15 light collector rows arranged in a module, for a total of 225 optics 118 and receiver assemblies 170, with a vertical spacing, or air gap, of 2.5 centimeters. The total module is 1.5 meters by 1.5 meters and 10 centimeters thick. FIG. 34b shows a cross sectional view. The light collector rows 280 are similar to the light collector rows 208 except that they are longer. FIG. 34 b shows a first group 1008 of solar energy collector modules and a second group 1010 of solar energy collector modules. As stated above, a light collector row can be referred to as solar energy collector module.

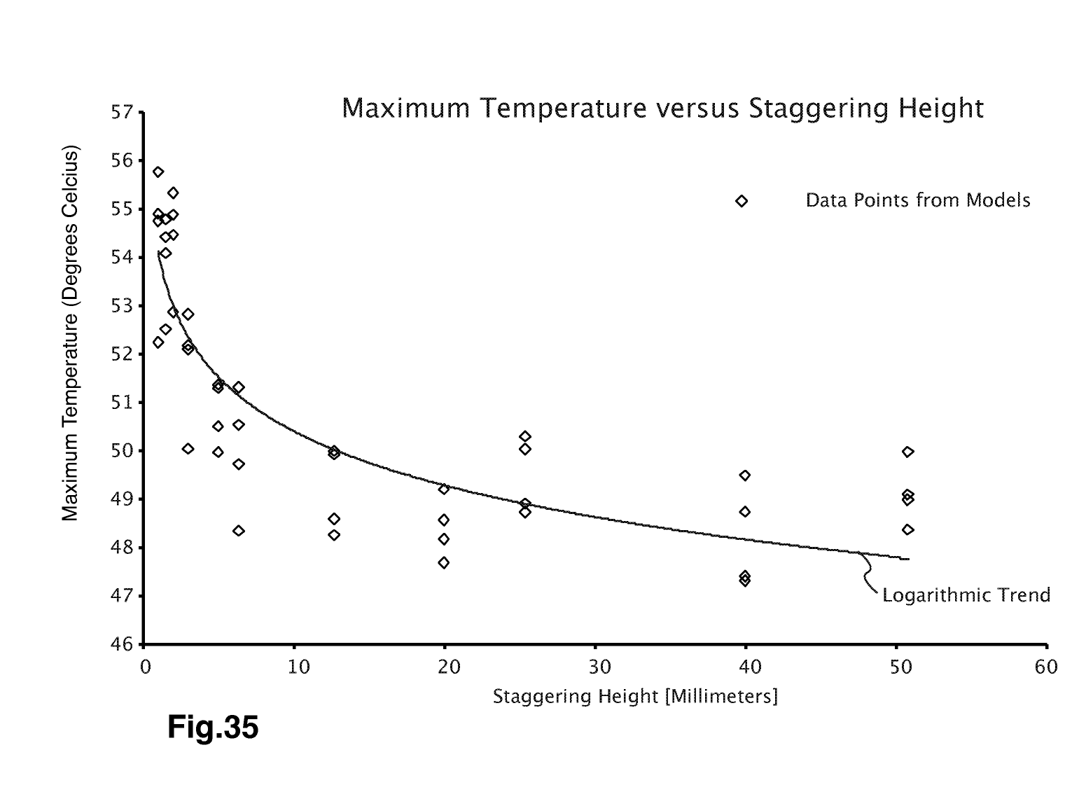

The light collector rows can vary in width and staggering height A lateral gap ranging from 1 to 50 centimeters wide is considered practical, and a vertical spacing, or air gap as small as five millimeters to as large as half of the light collector width can be considered. However, any suitable gap sizes and staggering gaps can be used. Preliminary thermal modeling analysis on the effect of staggering height on maximum temperature in the model is shown in FIG. 35. This has revealed that the gains in thermal dissipation as the vertical air gap height occur quickly and there is little effect on reducing maximum temperature beyond a air gap height of 10 millimeters.

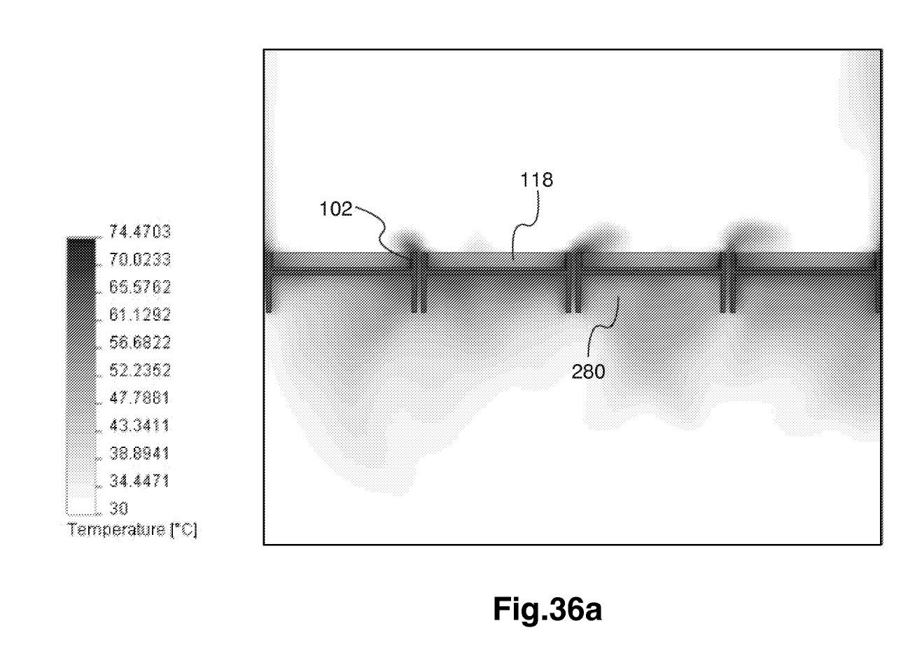

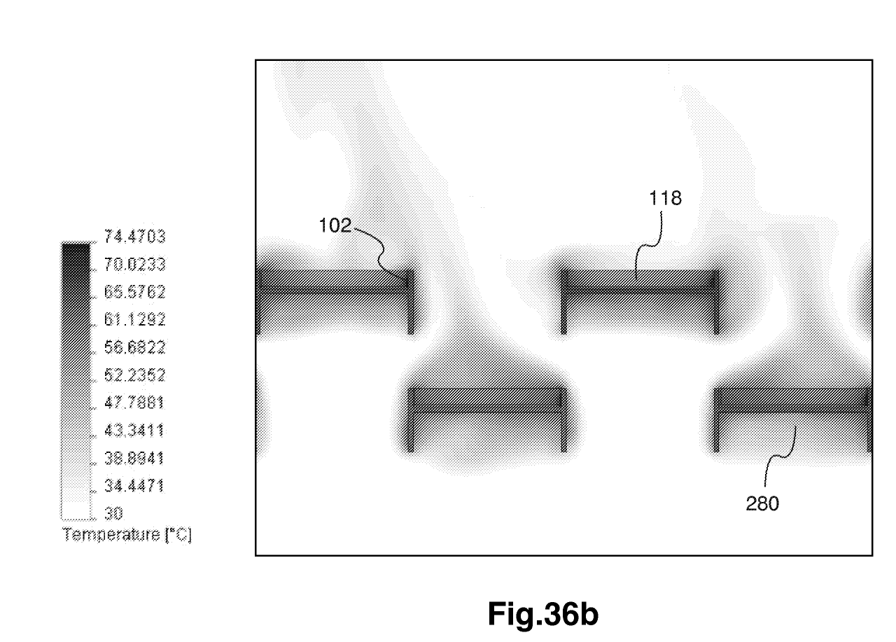

FIGS. 24 and 25 showed thermal models of heat dissipation under specified conditions for light collector rows that were very similar but not identical to the embodiment light collector rows 280 of FIGS. 34a and 34b. FIG. 36 shows the output from computational fluid dynamics thermal models using the embodiment with light collector rows 280. The maximum temperature reached when the light collector rows 280 are slightly spaced by 4 millimeters as in FIG. 36a is 74.5 degrees Celsius, the maximum temperature reached when the light collector rows 280 are vertically staggering by 38 millimeters is 67.5 degrees Celsius. Again, and as always, the vertically staggered light collector rows achieve lower temperatures and a reduction in dead-space.

In the preceding description, for purposes of explanation, numerous details are set forth in order to provide a thorough understanding of the embodiments of the invention. However, it will be apparent to one skilled in the art that these specific details are not required in order to practice the invention. In other instances, well-known electrical structures and circuits are shown in block diagram form in order not to obscure the invention.

The above-described embodiments of the invention are intended to be examples only. Alterations, modifications and variations can be effected to the particular embodiments by those of skill in the art without departing from the scope of the invention, which is defined solely by the claims appended hereto.

What is claimed is:

1. A photovoltaic tracking solar energy capturing and conversion system (101) comprising:
a first group (158,222) of spaced-apart solar energy collectors modules (100, 112,192,198) secured to a support (109);
a second group (160,224) of spaced-apart solar energy collectors modules (100, 112,192,198) secured to said support (109), each solar energy collector module (100, 112,192,198) of said first and second groups of solar energy collector modules including an array of photovoltaic cells (102, 170) associated with a respective optical light collector element (108,112,118, 120,122), the first and second groups of solar energy collectors modules defining two substantially parallel planes separated by an air gap, said air gap (162) dimensioned to ensure heat dissipation to prevent overheating of the photovoltaic cells (102,170), the first and second groups of solar energy collectors modules being staggered with respect to each other by an amount that allows the optical light collector elements (108,112,118, 120,122) of each solar energy collector module to be exposed to substantially equal levels of solar energy for capture by said optical light collector elements and associated photovoltaic cells, wherein the two parallel planes and the staggered positioning of the first and second groups of solar energy collector modules (100, 112,192,198) reduce wind load upon the solar energy collector modules; and
a tracking system (134,136, 254) that orients said support (109) to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

2. The system of claim 1 wherein the solar energy collector modules of the first group overly the solar energy collector modules of the second group to cast a shadow of the solar energy collector modules of the first group onto the solar energy collector modules of the second group without reducing the solar energy incident on the active photovoltaic cell (102).

3. The system of claim 2 wherein a width of the shadow is substantially equal to a width of an inactive area of the solar energy collector module of the second group.

4. The system of claim 1 wherein the optical light collector elements include a light guide (118).

5. The system of claim 1 wherein the optical light collector elements include a Fresnel lens (108).

6. The system of claim 1 wherein the optical light collector elements include a parabolic reflector (120).

7. The system of claim 1 wherein the optical light collector elements include Cassegrain optics (122).

8. The system of claim 1 wherein the optical light collector elements include a first and second optical elements (184,206).

9. A compact photovoltaic tracking solar energy capturing and conversion system comprising:
a first group of solar energy collectors modules secured to a support (109);
a second group of solar energy collectors modules secured to a support (109), each solar energy collector module of said first and second groups of solar energy collector modules including an array of photovoltaic cells each associated with a respective light guide optical concentrator, each solar energy collector module of the first and second groups being spaced apart from an adjacent solar energy collector module of its respective group by a distance substantially equal to a width of an active area of the photovoltaic cell, plus the width of a mounting section, the first and second groups of solar energy collector modules defining two substantially parallel planes, the substantially parallel planes being separated by an air gap, wherein the solar energy collector modules of the first and second groups are staggered with respect to each other by an amount that provides substantial equal exposure to solar energy minus a shadowing area (164) created by a lateral mounting portion (104,106) of the photovoltaic cell (102) to said support (109); and
a tracking system (134,136, 254) that orients said support (109) to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

10. The system of claim 9 wherein the solar energy collector modules of the first group overly the solar energy collector modules of the second group to cast a shadow of the solar energy collector modules of the first group onto the solar energy collector modules of the second group without reducing the solar energy incident on the active photovoltaic cell (102).

11. The system of claim 10 wherein a width of the shadow is substantially equal to a width of an inactive area of the solar energy collector module of the second group.

12. The system of claim 9 wherein the optical light collector elements include a light guide (118).

13. The system of claim 9 wherein the optical light collector elements include a Fresnel lens (108).

14. The system of claim 9 wherein the optical light collector elements include a parabolic reflector (120).

15. The system of claim 9 wherein the optical light collector elements include Cassegrain optics (122).

16. The system of claim 9 wherein the optical light collector elements include a first and second optical elements (184,206).

17. A method of dissipating heat accumulation in concentrated photovoltaic solar panels caused by an optic concentrator, the method comprising steps of:
providing a first group of solar energy collectors modules secured to a support (109);
providing a second group of solar energy collectors modules secured to the support (109), each collector module of said first and second groups of solar energy collector modules including an array of photovoltaic cells each associated with a respective optic concentrator, each solar energy collector module of the first and second groups of solar energy collector modules being spaced apart from another solar energy collector module of its respective group by a distance substantially equal to a width of an active area of a light capture area of a solar energy collector module, to create a heat dissipation pathway, said the first and second groups of solar energy collector modules defining substantially parallel planes separated by an air gap to create an additional heat dissipation pathway, wherein the solar energy collector modules from the first and second groups are staggered with respect to each other by an amount that provides substantially equal exposure to the solar energy minus a shadowing area created by a lateral mounting portion (104,106) of the photovoltaic cell (102) to said support (109); and
providing a tracking system (134,136, 254) that orients said support (109) to maximize the amount of solar energy captured by said staggered rows of solar energy collector modules to provide an optimum exposure of each optical light collector element to the solar energy and further increase the heat dissipation at the photovoltaic cell level for each position of the solar energy collector modules as provided by the tracking system.

18. The system of claim 17 wherein the solar energy collector modules of the first group overly the solar energy collector modules of the second group to cast a shadow of the solar energy collector modules of the first group onto the solar energy collector modules of the second group without reducing the solar energy incident on the active photovoltaic cell (102).

19. The system of claim 18 wherein a width of the shadow is substantially equal to a width of an inactive area of the solar energy collector module of the second group.

20. The system of claim 17 wherein the optical light collector elements include a light guide (118).

21. The system of claim 17 wherein the optical light collector elements include a Fresnel lens (108).

22. The system of claim 17 wherein the optical light collector elements include a parabolic reflector (120).

23. The system of claim 17 wherein the optical light collector elements include Cassegrain optics (122).

24. The system of claim 17 wherein the optical light collector elements include a first and second optical elements (184,206).
